(19) United States
(12) Patent Application Publication
(10) Pub. No.: US 2026/0321538 A1
(43) Pub. Date: Oct. 15, 2026

(54) DISCOVERY SAMPLING FOR DEFECT INSPECTION

(71) Applicant: KLA Corporation, Milpitas, CA (US)

(72) Inventors: Bradley Ries, San Jose, CA (US); Sayi Tummalapalli, San Ramon, CA (US)

(21) Appl. No.: 19/289,733

(22) Filed: Aug. 4, 2025

Related U.S. Application Data
(60) Provisional application No. 63/786,279, filed on Apr. 9, 2025.
(60) Provisional application No. 63/791,521, filed on Apr. 20, 2025.
(60) Provisional application No. 63/791,715, filed on Apr. 21, 2025.
(60) Provisional application No. 63/799,114, filed on May 2, 2025.
(60) Provisional application No. 63/799,104, filed on May 2, 2025.
(60) Provisional application No. 63/799,067, filed on May 2, 2025.

(51) Int. Cl. H01J 37/22; H01J 37/28

(52) U.S. Cl. CPC H01J 37/222; H01J 37/226; H01J 37/28

(57) ABSTRACT

An inspection system may include one or more controllers with processors configured to execute program instructions. The system may receive inspection data for samples from an inspection tool. The inspection data may be labeled into probable classes using a neural network model or unsupervised outlier detector. The system may assign diversity weight values associated with a discovery sampling scheme. A review sampling map may be generated based on the discovery sampling scheme. The map may include review locations on the samples. The system may direct a review tool to review the set of review locations on the samples.

### CROSS-REFERENCE TO RELATED APPLICATIONS

The present application claims the benefit under 35 U.S.C. § 119(e) of U.S. Provisional Application Ser. Nos. 63/786,279 filed on Apr. 9, 2025; 63/791,521 filed on Apr. 20, 2025; 63/791,715 filed on Apr. 21, 2025; 63/799,114 filed on May 2, 2025; 63/799,104 filed on May 2, 2025; and 63/799,067 filed on May 2, 2025; all of which are incorporated herein by reference in their entireties.

### TECHNICAL FIELD

The present disclosure relates to semiconductor inspection systems and methods, and more particularly to automated discovery sampling techniques for generating review sampling maps during inspection recipe creation.

### BACKGROUND

Semiconductor manufacturing processes involve complex inspection and review procedures to detect and classify defects on wafers. As device geometries continue to shrink and manufacturing processes become more intricate, the challenges in identifying defects of interest (DOIs) among millions of potential defects have increased significantly. Inspection systems typically generate large volumes of data that must be efficiently processed to isolate critical defects while minimizing false positives and unnecessary review operations. Traditional inspection and review workflows often rely on iterative scanning and manual tuning processes, which can be time-consuming and resource-intensive. There is therefore a need to develop systems and methods to address the above deficiencies.

### SUMMARY

In some embodiments, an inspection system is provided. The inspection system may include one or more controllers including one or more processors configured to execute program instructions causing the one or more processors to receive inspection data for one or more samples from an inspection tool. The one or more processors may assign sample scores to defect events from a hot scan associated with the inspection data. The one or more processors may select values of diversity weights for one or more diversity factors. The one or more processors may generate a review sampling map based on the sample scores and the diversity weights. The review sampling map may include a set of review locations on the one or more samples to review with a review tool. The diversity weights may control impacts of the one or more diversity factors on the review sampling map. The one or more processors may direct the review tool to review the set of review locations on the one or more samples.

In some embodiments, the sample scores may be proportional to outputs of an automated sensitivity tuner that selects values of detection parameters of a detection model to achieve a desired detection rate of probable defects relative to total defect count. The detection model may identify the defect events from the inspection data by comparing the inspection data to reference data and applying thresholds associated with the detection parameters.

In some embodiments, the automated sensitivity tuner may include an unsupervised model to assign outlier rankings to the defect events from the hot scan. The sample scores may be proportional to the outlier rankings.

In some embodiments, the unsupervised model may generate the outlier rankings by generating one or more attribute plots with the defect events from the hot scan associated with the inspection data. Axes of a particular one of the one or more attribute plots may include two or more of the detection parameters. The unsupervised model may assign the outlier rankings to the defect events based on the one or more attribute plots.

In some embodiments, the outlier rankings may be associated with a defect density in the one or more attribute plots.

In some embodiments, the outlier ranking for a particular defect event may be associated with one or more distances of the particular defect event from one or more clusters identified in the one or more attribute plots.

In some embodiments, the automated sensitivity tuner may include a supervised model. The sample scores may be proportional to an output of the supervised model.

In some embodiments, generating the review sampling map based on the sample scores and the diversity weights may include applying the diversity weights to the sample scores to generate diversity-weighted sample scores and generating the review sampling map based on the diversity-weighted sample scores.

In some embodiments, generating the review sampling map based on the sample scores and the diversity weights may include dividing a number of locations in the review sampling map into multiple bins representing different diversity factors and filling the bins based on the sample scores of the defect events.

In some embodiments, at least one of the one or more diversity factors may include diversity of locations across a sample of the one or more samples.

In some embodiments, at least one of the one or more diversity factors may include diversity of predefined regions associated with the one or more samples.

In some embodiments, the program instructions may further cause the one or more processors to label the defect events into two or more defect classes with a neural network model. The neural network model may be trained on defect data associated with the two or more defect classes. At least one of the one or more diversity factors may include class diversity associated with the two or more defect classes.

In some embodiments, the neural network model may be trained on data from at least one of multiple layers or multiple patterns.

In some embodiments, selecting the values of the diversity weights for the one or more diversity factors may include selecting the values of the diversity weights for two or more diversity factors.

In some embodiments, the values of the diversity weights may further include a global diversity weight controlling a global strength of multiple diversity factors.

In some embodiments, at least one of the one or more diversity factors may include a suppression factor that de-weights undesired defects.

In some embodiments, the undesired defects may include defects larger than a selected size.

In some embodiments, the undesired defects may include defects with known review signatures.

In some embodiments, at least one of the one or more diversity factors may further include a global suppression weight controlling a global strength of multiple suppression factors.

In some embodiments, the program instructions may be further configured to cause the one or more processors to generate an inspection recipe based on review data from the review tool associated with the set of review locations.

In some embodiments, selecting the values of the diversity weights for the one or more diversity factors may include providing a user with diversity controls associated with the diversity weights and receiving the values of the diversity weights based on the diversity controls.

In some embodiments, selecting the values of the diversity weights for the one or more diversity factors may include selecting the values of the diversity weights for the one or more diversity factors from a set of default values.

In some embodiments, an inspection system is provided. The inspection system may include an inspection sub-system, a review tool, and one or more controllers including one or more processors configured to execute program instructions causing the one or more processors to receive inspection data for one or more samples from an inspection tool. The one or more processors may assign sample scores to defect events from a hot scan associated with the inspection data. The one or more processors may select values of diversity weights for one or more diversity factors. The one or more processors may generate a review sampling map based on the sample scores and the diversity weights. The review sampling map may include a set of review locations on the one or more samples to review with the review tool. The diversity weights may control impacts of the one or more diversity factors on the review sampling map. The one or more processors may direct the review tool to review the set of review locations on the one or more samples.

In some embodiments, the inspection sub-system may include an optical inspection sub-system.

In some embodiments, the inspection sub-system may include a darkfield optical inspection sub-system.

In some embodiments, the review tool may include a scanning electron microscope.

In some embodiments, the sample scores may be proportional to outputs of an automated sensitivity tuner that selects values of detection parameters of a detection model to achieve a desired detection rate of probable defects relative to total defect count. The detection model may identify the defect events from the inspection data by comparing the inspection data to reference data and applying thresholds associated with the detection parameters.

In some embodiments, the automated sensitivity tuner may include an unsupervised model to assign outlier rankings to the defect events from the hot scan. The sample scores may be proportional to the outlier rankings.

In some embodiments, the automated sensitivity tuner may include a supervised model. The sample scores may be proportional to an output of the supervised model.

In some embodiments, the one or more diversity factors may include at least one of diversity of locations across a sample of the one or more samples, diversity of predefined regions associated with the one or more samples, or class diversity associated with two or more defect classes.

In some embodiments, at least one of the one or more diversity factors may include a suppression factor that de-weights undesired defects.

In some embodiments, an inspection method is provided. The method may include receiving inspection data for one or more samples from an inspection tool. The method may include assigning sample scores to defect events from a hot scan associated with the inspection data. The method may include selecting values of diversity weights for one or more diversity factors. The method may include generating a review sampling map based on the sample scores and the diversity weights. The review sampling map may include a set of review locations on the one or more samples to review with a review tool. The diversity weights may control impacts of the one or more diversity factors on the review sampling map. The method may include directing the review tool to review the set of review locations on the one or more samples

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF FIGURES

The numerous advantages of the disclosure may be better understood by those skilled in the art by reference to the accompanying figures.

FIG. 1A illustrates a block diagram of an inspection system, in accordance with one or more embodiments of the present disclosure.

FIG. 1B illustrates a block diagram of an inspection sub-system, in accordance with one or more embodiments of the present disclosure.

FIG. 1C illustrates a block diagram of a review sub-system, in accordance with one or more embodiments of the present disclosure.

FIG. 2 illustrates a flowchart of a method for processing inspection data, in accordance with one or more embodiments of the present disclosure.

FIG. 3 illustrates a plot of defect retention percentage versus total defect count, in accordance with one or more embodiments of the present disclosure.

FIG. 4 illustrates a scatter plot of two detection parameters, in accordance with one or more embodiments of the present disclosure.

FIG. 5A illustrates a defect map showing defect distribution during a hot scan, in accordance with one or more embodiments of the present disclosure.

FIG. 5B illustrates a set of defect maps illustrating different defect classifications, in accordance with one or more embodiments of the present disclosure.

FIG. 6 illustrates defect weight control, in accordance with one or more embodiments of the present disclosure.

FIG. 7A-7C illustrate defect analysis results without suppression or diversity emphasis, in accordance with one or more embodiments of the present disclosure.

FIG. 8A-8C illustrate defect analysis results with strong suppression and no diversity emphasis, in accordance with one or more embodiments of the present disclosure.

FIG. 9A-9C illustrate defect analysis results with moderate suppression and no diversity emphasis, in accordance with one or more embodiments of the present disclosure.

FIG. 10A-10C illustrate defect analysis results with moderate suppression and 100% region diversity, in accordance with one or more embodiments of the present disclosure.

FIG. 11A-11C illustrate defect analysis results with moderate suppression and 100% location diversity, in accordance with one or more embodiments of the present disclosure.

FIG. 12A-12C illustrate defect analysis results with moderate suppression and 100% class diversity, in accordance with one or more embodiments of the present disclosure.

FIG. 13A-13C illustrate defect analysis results with moderate suppression and 100% mixed diversity, in accordance with one or more embodiments of the present disclosure.

FIG. 14A-14C illustrate defect analysis results with moderate suppression and 70% mixed diversity, in accordance with one or more embodiments of the present disclosure.

FIG. 15 illustrates defect sampling distributions for different defects of interest using different sampling techniques, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for automated generation of review sampling maps for review with a review tool (e.g., a scanning electron microscope (SEM), or the like) based on adjustable diversity weights associated with sampling preferences. This automated generation of review sampling maps may be referred to herein as discovery sampling and may be, but is not required to be, used during generation of an inspection recipe.

When developing an inspection recipe for a new layer or process, a user may have limited information about the defect types and noise characteristics of the samples and/or an inspection tool used to inspect the samples for defects. In many cases, ground truth data related to defects of interest (DOIs) for inspection is captured by reviewing (e.g., analyzing portions of fabricated samples using a review tool (e.g., a SEM, or the like). However, review tools are typically slow and it is often impractical, undesirable, or in some cases impossible to review all potential defects.

It may be desirable to capture a wide range of DOIs in a review sampling map to ensure that models used for defect detection and/or nuisance filtering may be trained with sufficient data. In embodiments, automated discovery sampling utilizes adjustable diversity weights associated with two or more diversity factors (e.g., types of diversity). For example, diversity factors may include, but are not limited to, diversity of locations across a sample, diversity of predefined regions associated with the one or more samples, or class diversity associated with the two or more probable classes. In this way, the review sampling map may be tailored to the needs of a particular application. Automated discovery sampling may further include suppression weights to suppress defects that may be relatively less important for review including, but not limited to, large defects or defects with a known signature (e.g., obvious defects). In this way, review time may be more efficiently used to analyze critical DOIs and/or DOIs near a noise floor.

This process may enable users with a range of experience levels to set up recipes appropriate for high-volume manufacturing (HVM) environments. In some embodiments, the process may reduce the need for iterative SEM reviews while achieving required sensitivity levels and significantly lowering test time.

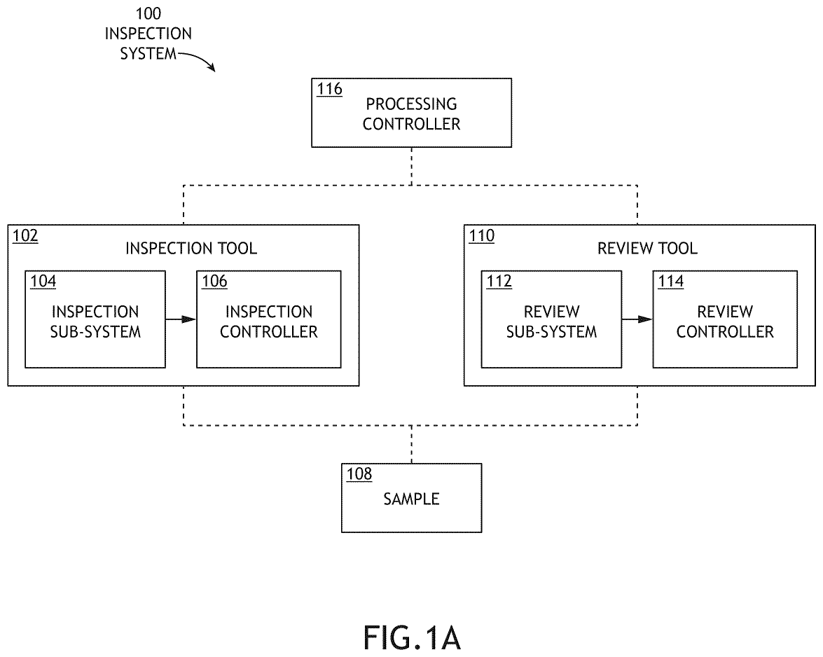

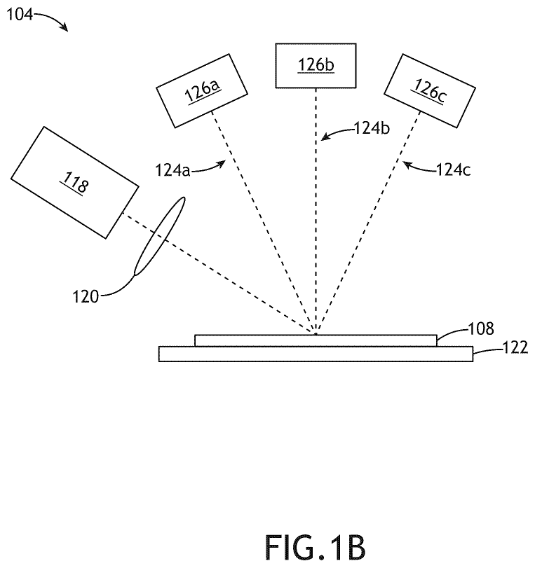

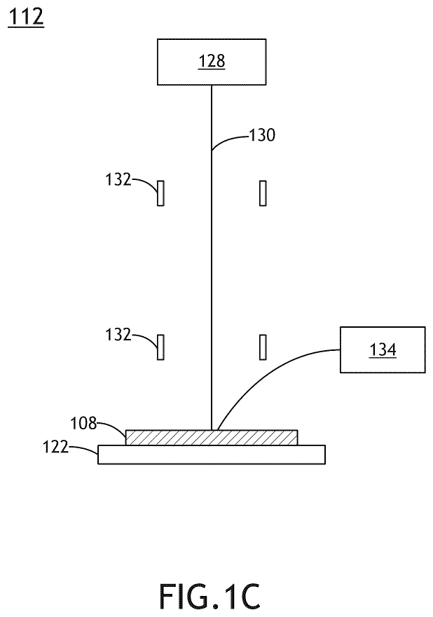

Referring now to FIGS. 1A-15, systems and methods providing automated discovery review for inspection recipe generation are described, in accordance with one or more embodiments of the present disclosure.

FIG. 1A illustrates a block diagram of an inspection system 100, in accordance with some embodiments of the present disclosure.

In embodiments, the inspection system 100 includes an inspection tool 102 with an inspection sub-system 104 to generate inspection data for one or more samples 108.

The sample 108 may include a substrate formed of a semiconductor or non-semiconductor material (e.g., a wafer, or the like). For example, a semiconductor or non-semiconductor material may include, but is not limited to, monocrystalline silicon, gallium arsenide, and indium phosphide. The sample 108 may further include one or more layers disposed on the substrate. For example, such layers may include, but are not limited to, a resist, a dielectric material, a conductive material, and/or a semiconductive material. Many different types of such layers are known in the art, and the term sample as used herein is intended to encompass a sample on which all types of such layers may be formed. One or more layers formed on a sample 108 may be patterned or unpatterned. For example, a sample may include a plurality of dies, each having repeatable patterned features. Formation and processing of such layers of material may ultimately result in completed devices. Many different types of devices may be formed on a sample, and the term sample as used herein is intended to encompass a sample on which any type of device known in the art is being fabricated.

The inspection sub-system 104 may generate inspection data of a sample 108 using any suitable technique. For example, the inspection sub-system 104 may be an imaging system that may generate one or more images of the sample 108 (e.g., darkfield images, brightfield images, or the like). In some cases, the inspection sub-system 104 may be an optical imaging system suitable for HVM that generates images. Non-limiting examples of an inspection tool 102 include Voyager or Puma tools from KLA Corporation.

In embodiments, the inspection system 100 includes a review tool 110 with a review sub-system 112 to review selected locations on a sample 108. In some cases, the review sub-system 112 may have a higher resolution but a slower throughput than the inspection sub-system 104. For example, the review sub-system 112 may include, but is not limited to, a scanning electron microscope (SEM). In this way, review data from the review tool 110 may operate as ground truth data that may be used to train defect detection models to identify defects from the HVM-suitable inspection tool 102.

The inspection system 100 may include one or more controllers integrated within and/or communicatively coupled with the inspection tool 102 and/or the review tool 110. For example, FIG. 1A depicts a non-limiting configuration of an inspection system 100 with an inspection controller 106 associated with the inspection tool 102, a review controller 114 associated with the review tool 110, and a processing controller 116 communicatively coupled with the inspection tool 102 and/or the review tool 110. More generally, the inspection system 100 may include any number of controllers integrated within and/or communicatively coupled with any components of the inspection system 100 or external components.

Any of the controllers of the inspection system 100 (e.g., the inspection controller 106, the review controller 114, the processing controller 116, or any other controllers) may include one or more processors configured to execute program instructions maintained on memory, or a memory medium. In this regard, the one or more processors of the controllers may execute any of the various process steps described throughout the present disclosure.

The one or more processors of any controller may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In some embodiments, the one or more processors may be embodied as a desktop computer, mainframe computer system, workstation, image computer, parallel processor, networked computer, or any other computer system configured to execute a program configured to operate or operate in conjunction with the inspection system 100, as described throughout the present disclosure.

The memory may include any storage medium known in the art suitable for storing program instructions executable by the associated one or more processors. For example, the memory may include a non-transitory memory medium. By way of another example, the memory may include, but is not limited to, a read-only memory (ROM), a random-access memory (RAM), a magnetic or optical memory device (e.g., disk), a magnetic tape, a solid-state drive and the like. It is further noted that memory may be housed in a common controller housing with the one or more processors. In some embodiments, the memory may be located remotely with respect to the physical location of the one or more processors and controller. For instance, the one or more processors of the controller may access a remote memory (e.g., server), accessible through a network (e.g., internet, intranet and the like).

In embodiments, computational and/or control tasks may be implemented by any controller or combination of controllers within the inspection system 100 including, but not limited to, the inspection controller 106, the review controller 114, or the processing controller 116. In some cases, different tasks may be performed by different controllers. As an illustration, the inspection controller 106 may perform tasks related to the operation of and/or analysis of data from the inspection sub-system 104, the review controller 114 may perform tasks related to the operation of and/or analysis of data from the review sub-system 112, and the processing controller 116 may perform post-processing operations for generating an inspection recipe based on data from the inspection tool 102 and/or the review tool 110. As another illustration, the processing controller 116 may perform steps such as, but not limited to, model generation, model training, or model implementation for the inspection tool 102 and/or the review tool 110. In this way, although FIG. 1A shows a configuration where the inspection tool 102 and the review tool 110 each have dedicated controllers, the system may generally have any number of controllers associated with any components and/or dedicated controllers. In some cases, the one or more controllers of the inspection system 100 may comprise a single controller that performs the functions of the inspection controller 106, review controller 114, and processing controller 116.

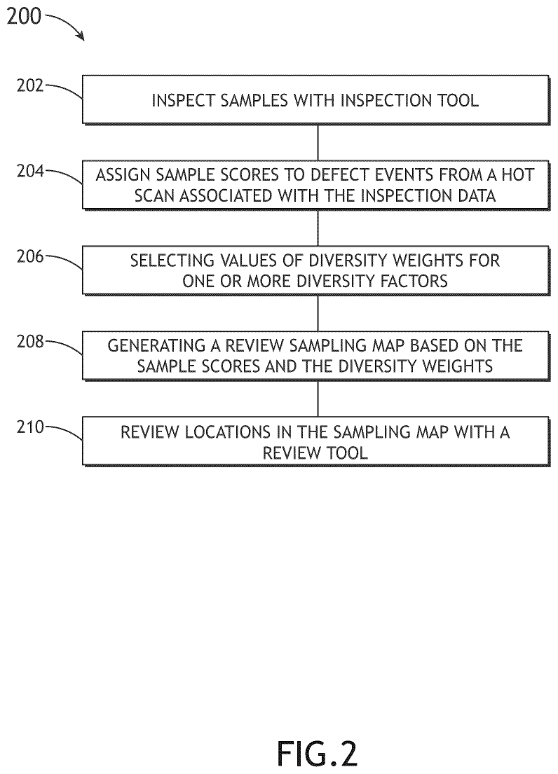

Referring now to FIGS. 2-15, a method for discovery review sampling is described, in accordance with one or more embodiments of the present disclosure.

FIG. 2 is a flow diagram illustrating steps performed in a method 200 for discovery review sampling, in accordance with one or more embodiments of the present disclosure. Applicant notes that the embodiments and enabling technologies described previously herein in the context of the inspection system 100 should be interpreted to extend to the method 200. For example, any of the steps of the method 200 may be performed directly or indirectly (e.g., by generating control signals to direct another component to perform a step) by any of the controllers of the inspection system 100 alone or in combination. It is further noted, however, that the method 200 is not limited to the architecture of the inspection system 100.

In embodiments, the method 200 includes a step 202 of receiving inspection data for one or more samples from an inspection tool. The inspection data may be received by the inspection controller 106 of the inspection system 100. The inspection controller 106 may receive the inspection data through a communication interface or data transfer mechanism connecting the inspection sub-system 104 to the inspection controller 106. The one or more processors of the inspection controller 106 may then store the received inspection data in the memory for further processing and analysis in the subsequent steps of the method 200.

The inspection data may have any format suitable for including information indicative of the presence or absence of one or more defects. For example, the inspection data may be in a format suitable for comparison with reference data known to be free of defects using a detection model.

In embodiments, a detection model may identify potential defects (referred to herein as defect events) on the one or more samples 108 by comparing the inspection data to reference data and applying thresholds associated with the detection parameters. As an illustration in the context of an image-based detection model, the detection model may compare pixel intensities or other image characteristics between corresponding regions of an inspection image (e.g., an image of a portion of a sample 108 being inspected) and a reference image (e.g., a real or simulated image of a corresponding portion of the sample 108 known to be free of defects). The detection model may then apply processing steps such as, but not limited to, filtering, clustering, or classification steps to distinguish probable DOIs from nuisance events, where the operation of these steps may be controlled by various detection parameters. For example, the detection parameters may define thresholds or other controls that determine whether variations between the inspection data and reference data are classified as potential defects.

In some cases, the inspection data received in step 202 may correspond to or may be used to generate a “hot scan” of the one or more samples 108. A hot scan may refer to an inspection process where the inspection sub-system 104 and/or the detection model are configured to capture a wide range of potential defects or anomalies that may be at or near a noise floor of the sample 108 and/or the inspection sub-system 104, including those that may later be classified as DOIs or nuisances. For example, the detection model may run with a default set of detection parameters that provide high sensitivity to a wide range of defects (e.g., low thresholds). For this reason, the hot scan may also be referred to as a default scan. This approach may provide a comprehensive dataset for subsequent analysis and parameter optimization steps in the method 200.

In some cases, though not explicitly shown in FIG. 2, the method 200 may also implement a neural network model, which may be referred to as a mother model, to perform an initial classification of defect events associated with the inspection data generated in step 202. In some cases, the neural network model may perform an initial classification of defect events associated with a hot scan or default scan.

The neural network model may assign probabilities or confidence scores for various defect categories. The detection model may classify the defect events into any number or type of categories. As an illustration, the neural network model may classify defect events in the hot scan into high-confidence DOIs, low-confidence DOIs, high-confidence nuisance events, and low-confidence nuisance events. As another illustration, the neural network model may classify defect events by defect type. However, these are merely illustrations and not limiting. The neural network model (e.g., the mother model) may classify defect events from the hot scan into any number or type of classes.

The neural network model may be trained using a diverse set of training data comprising historical inspection data from multiple layers and defect types. In this way, the neural network model may be generalized beyond the current layer of a sample 108 being inspected and/or the particular process used. This training data may include, but is not limited to, images of known defects of interest (DOIs) and nuisances, along with associated metadata such as defect size, location, and classification. The model may utilize a deep learning architecture, such as a convolutional neural network (CNN), to extract relevant features from the input data and learn to distinguish between various DOIs and nuisances.

In embodiments, the method 200 includes a step 204 of assigning sample scores to defect events from a hot scan associated with the inspection data. It is contemplated herein that it may be impractical or impossible to include all defect events from the hot scan. Accordingly, in this configuration, the sample scores may provide a metric for prioritizing defect events to include in the sampling plan. The total number of defect events included in the review sampling map may be determined based on factors such as available review resources and desired coverage of the sample. In some cases, the review sampling map may include 100-2000 locations out of tens of thousands of defect events in the hot scan, though this is merely in an illustration.

The sample scores may utilize any metric related to a confidence of a classification of a defect event as a probable DOI or a probable nuisance. For example, the sample score may be a numerical value assigned to each defect event detected during the hot scan, representing the likelihood of that event being a DOI.

In some cases, the sample scores are proportional to outputs of an automated sensitivity tuner (AST) that selects values of detection parameters of a detection model to achieve a desired detection rate of probable defects relative to total defect count, wherein the detection model identifies the defect events from the inspection data by comparing the inspection data to reference data and applying thresholds associated with the detection parameters. An AST is generally described in U.S. patent application Ser. No. 19/289,391 filed on Aug. 4, 2025, which is incorporated herein by reference in its entirety. When performed with the inspection system 100, this step 204 may be implemented by any of the controllers of the inspection system 100 alone or in combination.

It is contemplated herein that the defect detection parameters may have many interrelated effects such that determining suitable values for these parameters may be complex, tedious, and time consuming. For example, a detection model may have five, ten, or more detection parameters that may provide interrelated effects. As a result, the task of selecting suitable values of the detection parameters suitable for distinguishing probable DOIs from probable nuisances is multi-dimensional selection problem (e.g., an n-dimensional selection problem for a detection model with n parameters that may be tuned).

In embodiments, the AST generates a receiver operating characteristic (ROC) curve describing possible operating points of the detection model. For example, an ROC curve may plot a retention rate of probable DOIs as a function of total number of defect events, where each point on the ROC corresponds to the operation of the detection model with different values of the detection parameters (and thus different operating thresholds) as determined by the AST. In this way, each point on the ROC (e.g., each operating point of the detection model) may be the result of an n-dimensional analysis of the detection parameter space (e.g., n detection parameters being tuned).

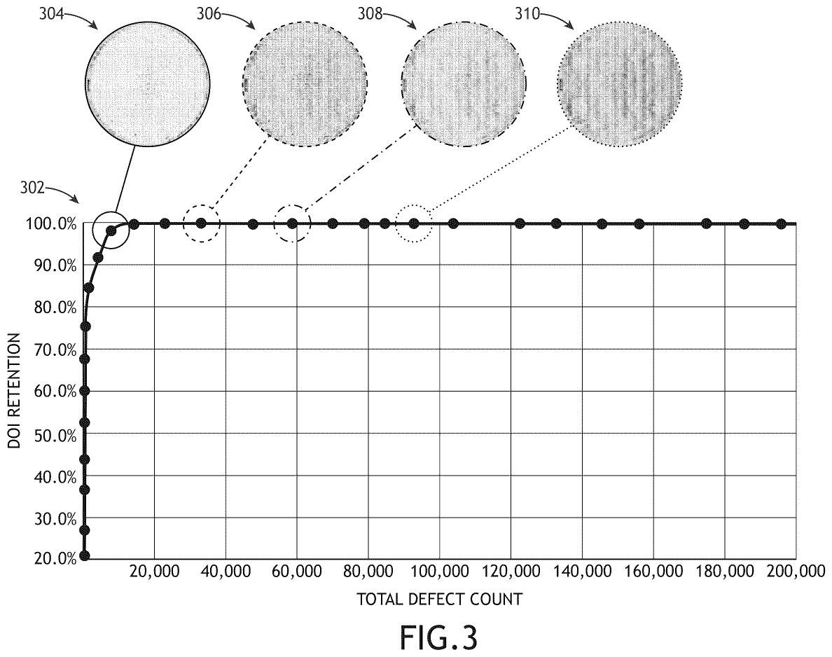

FIG. 3 illustrates a receiver operating characteristic (ROC) curve 302, in accordance with one or more embodiments of the present disclosure. In FIG. 3, the defect retention rate (e.g. a retention rate of probable DOIs) is plotted relative to total defect count (e.g., a total number of events identified by a detection model). It may be the case that a defect model may not perfectly distinguish probable DOIs from probable nuisances. Rather, a defect model may typically output defect events that include both probable DOIs as well as probable nuisances and, in some cases, may identify many more probable nuisances than probable DOIs. In most cases, increasing the total defect count from the defect model results in higher percentages of probable DOIs. Further, as shown in FIG. 3, the ROC curve may show a rapid increase in DOI retention rate followed by a more gradual increase until or approaching 100%.

FIG. 3 additionally depicts insets associated with defect maps associated with selected operating points of the ROC curve 302. In particular, FIG. 3 depicts a first defect map 304, a second defect map 306, a third defect map 308, and a fourth defect map 310, each at increasing total defect counts as seen by the increasing density in the associated defect maps.

It is contemplated herein that generating an ROC curve may allow for the dynamic selection of a desired performance level of the detection model based on the requirements of any particular application. In particular, each point on the ROC curve represents a different balance between number of total defect events (e.g., total defect count) and number of probable DOIs captured by particular settings of the detection model.

When generating the ROC curve, the AST relies on some classification of defect events into probable DOIs or probable nuisances. The AST may utilize any combination of machine learning techniques to classify defect events when generating an ROC curve and/or providing detection parameter values associated with a selected operating point including, but not limited to, supervised learning, unsupervised learning, semi-supervised learning, or reinforcement learning. As used herein, the term “machine learning technique” refers to a computational method that uses algorithms and statistical models to enable computer systems to improve their performance on a specific task through experience. In the context of the present disclosure, machine learning techniques may include supervised learning, unsupervised learning, or reinforcement learning approaches applied to analyze inspection data and optimize detection parameters. “Supervised learning” refers to a type of machine learning where the algorithm is trained on a labeled dataset, meaning the input data is paired with corresponding output labels. “Unsupervised learning” refers to a type of machine learning where the algorithm analyzes unlabeled data to find patterns or groupings without pre-existing output labels.

In embodiments, if ground truth data including inspection images of known DOIs and known nuisances is available, the AST may utilize a supervised machine learning technique that utilizes this ground truth data (e.g., as training data). This ground truth data may be derived from any source including, but not limited to, inspection and review of fabricated samples (e.g., with an inspection sub-system 104 and a review tool 110) or from historical datasets that may be associated with various processes or fabricated features. The AST may then identify the detection parameters that provide selected detection rates of probable DOIs and probable nuisances (e.g., associated with a selected operating point of an ROC curve) based on these supervised classifications. Further, the sample scores in step 204 may be proportional to a confidence associated with such supervised classifications.

In embodiments, the AST may use unsupervised techniques to distinguish probable DOIs from probable nuisance events without relying on ground truth data whether or not it is available. In the context of the present disclosure, unsupervised learning may involve the AST analyzing inspection data to identify potential defects of interest and nuisances based on inherent patterns in the data, without relying on pre-classified examples.

For example, the AST may perform a multi-dimensional analysis of the hot scan (e.g., including defect events from the detection algorithm with parameters selected to capture defects are or near a noise floor) in an attribute space corresponding to at least some of the detection parameters that are being tuned. As an illustration, the unsupervised AST may generate or consider one or more attribute plots of the hot scan defect events, where an attribute plot may describe the defect events as a function of two or more detection parameters of the detection model that are being tuned. Put another way, two or more detection parameters may be the axes of an attribute plot.

The AST may then utilize an outlier detection algorithm to identify potential outliers in the multi-dimensional attribute space. For example, the AST may utilize clustering algorithms such as, but not limited to, k-means or Gaussian mixture models to identify clusters in the multi-dimensional parameter space and identify outliers based on the clusters. It is contemplated herein that clusters of defect events may likely represent background data or nuisances not critical to operation of a fabricated device on the sample 108. In contrast, outliers or defect events that are relatively separated from the clusters may be more likely to be DOIs.

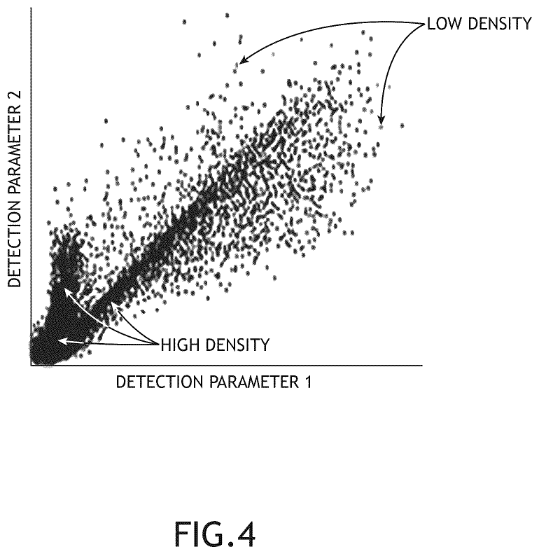

FIG. 4 illustrates a non-limiting example of a two-dimensional attribute plot, in accordance with one or more embodiments of the present disclosure. In FIG. 4, detection parameter 1 is plotted on the x-axis and detection parameter 2 is plotted on the y-axis, with each point representing a detected event from the inspection data. In this way, the attribute plot in FIG. 4 is a two-dimensional plot. However, an attribute plot may generally have any number of dimensions associated with any number of detection parameters. In some cases, an attribute plot includes n dimensions, where n is a number of the detection parameters being tuned.

As shown in FIG. 4, plotting defect events in a multi-dimensional space may reveal high-density clusters of defect events that may be more likely to be nuisances as well as reveal isolated or low-density regions of defect events that may be more likely to be DOIs.

In embodiments, the AST assigns an outlier ranking to each of the defect events in an attribute plot, which may operate as an unsupervised metric for ranking outlier events. The AST may then classify the defect events as probable defects of interest or probable nuisances based on the outlier rankings. As described above, these classifications may be used when performing multi-parameter optimization to select values of detection parameters when generating an ROC curve. Further, the sample scores in step 204 may be proportional to the outlier rankings generated by the unsupervised model.

The outlier rankings may be based on any criteria. For example, the outlier rankings may be associated with defect density in one or more attribute plots, where defect events in relatively low-density regions of the plot may receive a higher outlier ranking than defect events in relatively high-density regions of the plot. As another example, the outlier rankings may be associated with one or more distances of particular defect events from one or more clusters identified in the attribute plots. In this case, defect events located relatively further from the clusters in the attribute space may be assigned higher outlier rankings than defect events located relatively closer to or within any of the clusters.

The unsupervised AST may utilize any number of attribute plots to analyze the inspection data. It is contemplated herein that certain combinations of detection parameters may provide more pronounced clusters than others and may thus be more suitable for distinguishing between at least certain types of probable DOIs and probable nuisances. Put another way, each attribute plot may provide a different perspective on the inspection data by focusing on different combinations of detection parameters.

Referring again to FIG. 2, the method 200 includes a step 206 of selecting values of diversity weights for one or more diversity factors. Such a configuration may be referred to as a diversity sampling scheme. The method 200 may further include a step 208 of generating a review sampling map based on the sample scores and the diversity weights. In this way, the review sampling map may take into account the diversity weights assigned in step 206.

Diversity factors may correspond to metrics for measuring or characterizing diversity of defect events included in a review sampling map. Diversity weights may then control the impact of one or more diversity factors in a final review sampling map. These diversity weights may be dynamically adjusted to tailor the diversity of defect events included in a review sampling map. As is described in greater detail below, the defect weights may in some applications be selected or otherwise controlled by a user.

One nonlimiting example of a diversity factor includes diversity of locations across a sample. This diversity factor may facilitate the sampling of defect events distributed across different areas of the sample 108 and mitigate concentrated sampling of hot spots.

Another nonlimiting example of a diversity factor includes diversity of predefined regions associated with a samples 108. This diversity factor may facilitate selecting defects from various predefined areas of interest on the sample 108, such as edge regions, regions associated with different radial locations on a sample 108, different die, specific structures within dies, or the like.

Another nonlimiting example of a diversity factor includes class diversity. This diversity factor may relate to sampling defects across different probable classes. Various types of classes may be considered. For example, the classes may relate to whether a defect event is a probable defect or a probable nuisance. As another example, the classes may relate to a confidence level such as. but not limited to, high-confidence DOIs, low-confidence DOIs, high-confidence nuisances, and low-confidence nuisances. As another example, the classes may relate to different types of defects (e.g., different fabrication issues).

The classes may be generated using any suitable technique. In embodiments, defect data from the hot scan is labeled using a neural network model (e.g., a mother model) as described previously herein.

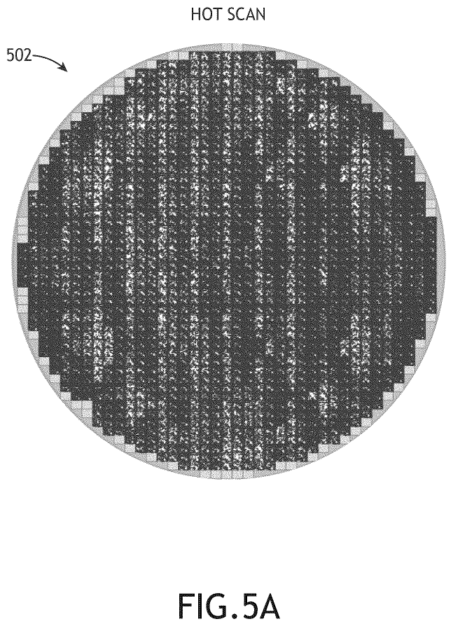

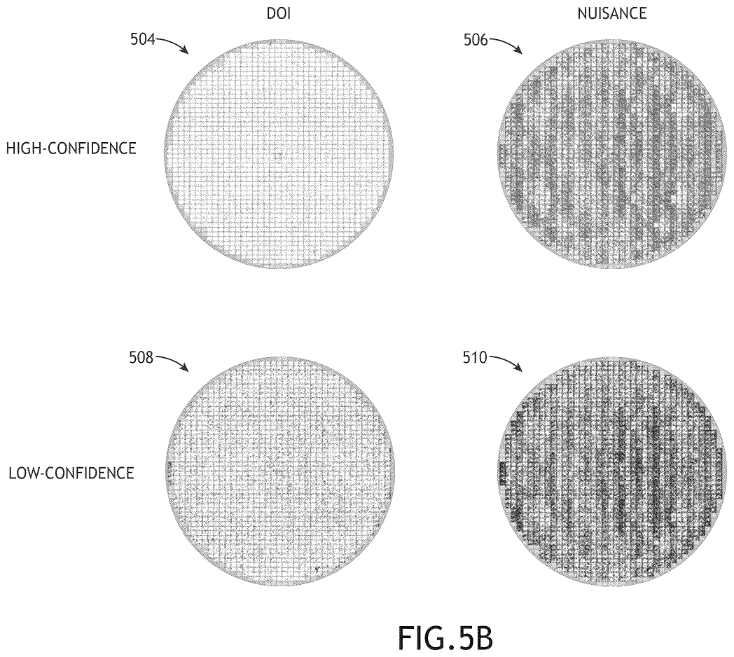

Referring now to FIGS. 5A-5B, FIGS. 5A-5B depict the classification of potential defects (e.g., defect events, or the like) into multiple probable classes. For example, FIGS. 5A-5B may be, but are not required to be, generated using a neural network model.

FIG. 5A illustrates a hot scan defect map 502 showing the distribution of defects detected during a hot scan of a sample. The hot scan defect map 502 displays a representation of a sample 108 with a multitude of potential defects (e.g., defect events). For example, the hot scan defect map 502 may be captured by the inspection sub-system 104 with sensitivity levels selected to probe the noise floor associated with the sample 108 and/or the inspection sub-system 104. FIG. 5B illustrates a set of defect maps illustrating different defect classifications, in accordance with one or more embodiments of the present disclosure. In particular, FIG. 5B depicts a high-confidence DOI defect map 504, a high-confidence nuisance defect map 506, a low-confidence DOI defect map 508, and a low-confidence nuisance defect map 510. As described above, the defect maps 504-510 in FIG. 5B may be generated by a neural network model (e.g., a mother model), an unsupervised outlier detector, or a combination thereof.

Referring again to FIG. 2, in some cases, the diversity factors may include one or more suppression factors, which may encourage sampling diversity by de-weight certain undesired defects (e.g., defect events). The use of suppression factors may further enable more efficient review of challenging DOIs near a noise floor. For example, a suppression factor may de-emphasize large defects (e.g., defects greater than a selected size). As another example, a suppression factor may de-emphasize defects with a clear or well-known review signature (e.g., obvious defects).

In some embodiments, the diversity weights include one or more global weights that impact multiple (e.g., two or more diversity factors). For example, a global weight may control whether and to what extent the diversity weights associated with particular diversity factors are applied when generating a review sampling map. As another example, a global weight may control whether and to what extent suppression weights associated with suppressing certain defects are applied when generating a review sampling map. In a general sense, any number of global weights may be used to provide tailored control over any number of diversity or suppression factors.

Further, the diversity weights may represented in any format including, but not limited to, fractions, percentages, or any suitable value that influences sampling.

Referring now to step 208, sample score and the diversity weights may be used to populate a review sampling plan using any suitable technique.

For example, a number of locations in the review sampling plan may be divided into one or more groups (e.g., bins) representing different diversity factors, where the various bins are filled based on the sample score. For example, the defect events may be added to the various bins in order of the sample score until the bins are full. The total number of defect events included in the review sampling map may be determined based on factors such as available review resources and desired coverage of the sample. In some cases, the review sampling map may include 100-2000 locations, though this is merely in an illustration.

As another example, the step 208 may include applying the diversity weights to the sample scores to generate diversity-weighted sample scores followed by generating the review sampling map based on the diversity-weighted sample scores. In this way, the diversity weights may directly impact the sample scores (e.g., as diversity-weighted sample scores) such that the available number of locations in the review sampling plan may be filled based on the diversity-weighted sample scores that preferentially include a desired mix of diversity factors and/or suppression factors.

Using sample scores in discovery sampling may offer several benefits. It may allow for more efficient use of review resources by prioritizing defect events that are most likely to be DOIs or that provide the most valuable information for improving the detection model. The incorporation of diversity weights and suppression weights in the sample score calculation may help balance the need for comprehensive coverage with the focus on critical defects. This approach may lead to more robust and representative review sampling maps, potentially improving the overall effectiveness of the inspection and review process.

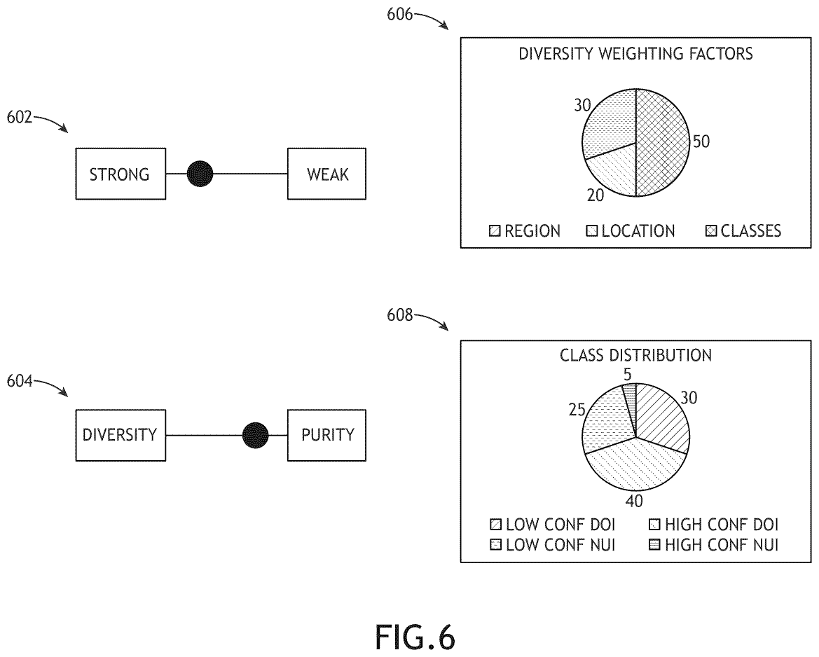

Referring now to FIGS. 6-14C, examples of discovery sampling are described.

FIG. 6 illustrates defect weight selection, in accordance with one or more embodiments of the present disclosure. For example, FIG. 6 may depict diversity controls that may be presented to a user that may allow the user to adjust the diversity weights.

Panels 604-610 illustrate controls for adjusting diversity weights associated with different diversity factors. For example, panel 608 depicts a selected diversity weighting scheme in which region diversity is given a 30% diversity weight, location diversity is given a 20% diversity weight, and class diversity is given a 50% diversity weight. Panel 610 depicts additional diversity weights (e.g., sub-weights) associated with four different classes relevant to with class diversity weighting (e.g., with the 50% diversity weight in panel 608), where low-confidence DOIs are weighted at 30%, high-confidence DOIs are weighted at 40%, low-confidence nuisance are weighted at 25%, and high-confidence nuisances are weighted at 5%. It is noted that this weighting scheme may prioritize the sampling of high-confidence DOIs and suppress (e.g., deprioritize) high-confidence nuisances. It is to be understood that any of the specific weighting percentages or sub-weighting percentages above are shown solely for illustrative purposes and should not be interpreted as limiting the spirit or scope of the present disclosure.

Panels 602-604 represent controls for global weights. In particular, panel 602 represents a control for a global suppression weight that controls the extent to which certain defects types (e.g., relatively large defect types that are larger than a threshold size) are suppressed.

Panel 604 represents a control for a global diversity weight that controls the extent to which various diversity factors (e.g., as depicted in panels 606-608) are considered when generating a review sampling plan. For example, selecting a strong global diversity weight (e.g., 100%, 1, or the like) may provide that all of the locations in the review sampling map are allocated into the selected diversity bins with relative bin sizes defined by the weighting scheme (e.g., as shown in panels 606-608). Decreasing the global diversity weight (e.g., to a value less then 100%, less than 1, or the like) may provide that only a fraction of the locations in the review sampling map are allocated into the selected diversity bins with relative bin sizes defined by the weighting scheme. In this configuration, the remaining locations may be filled based only on the sample score. Further, the locations associated with the diversity weighting scheme may be filled before or after the locations associated only with the sample score.

It is noted that the FIG. 6 and the associated descriptions are provided solely for illustrative purposes and should not be interpreted as limiting the scope of the present disclosure. For example, panel 602 and panel 604 are presented as sliders (e.g., suitable for control by a user via a graphical user interface). However, global weights and/or any specific factors (e.g., defect type suppression factors, class distribution factors, diversity weights, or the like) may be defined and/or controlled via any technique including, but not limited to, a graphical user interface of any type, a text interface, an application interface, via an algorithm, or via an automation.

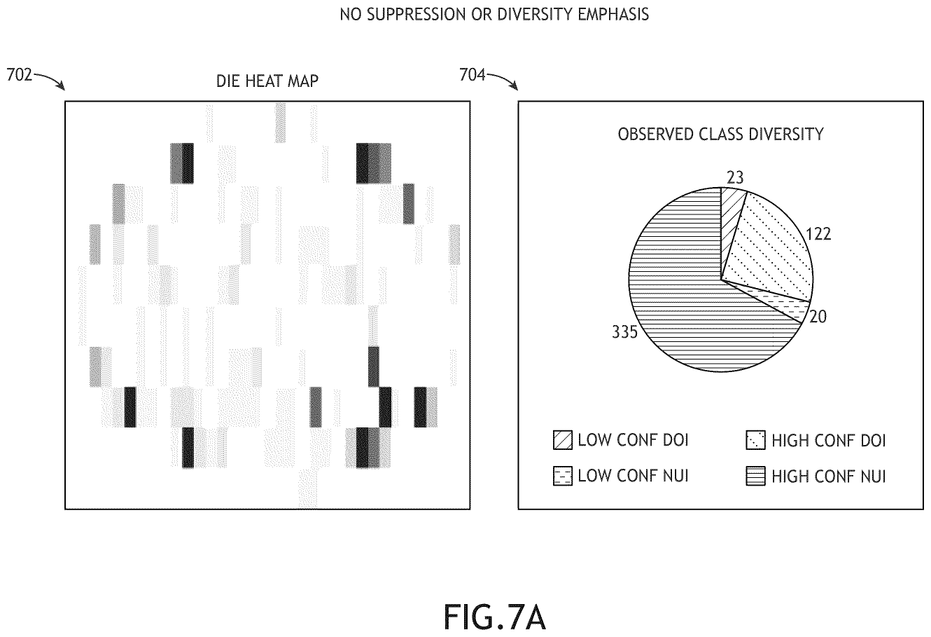

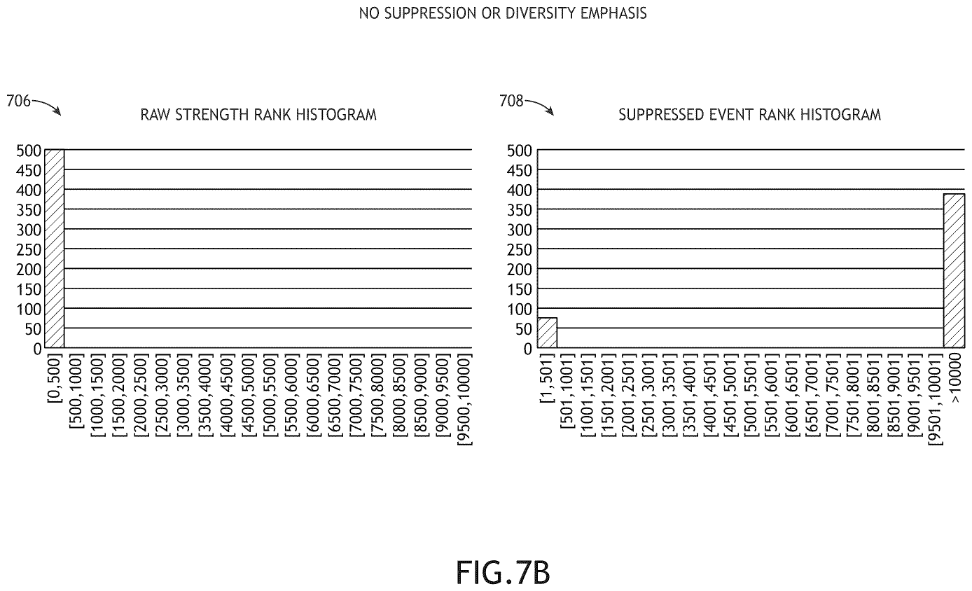

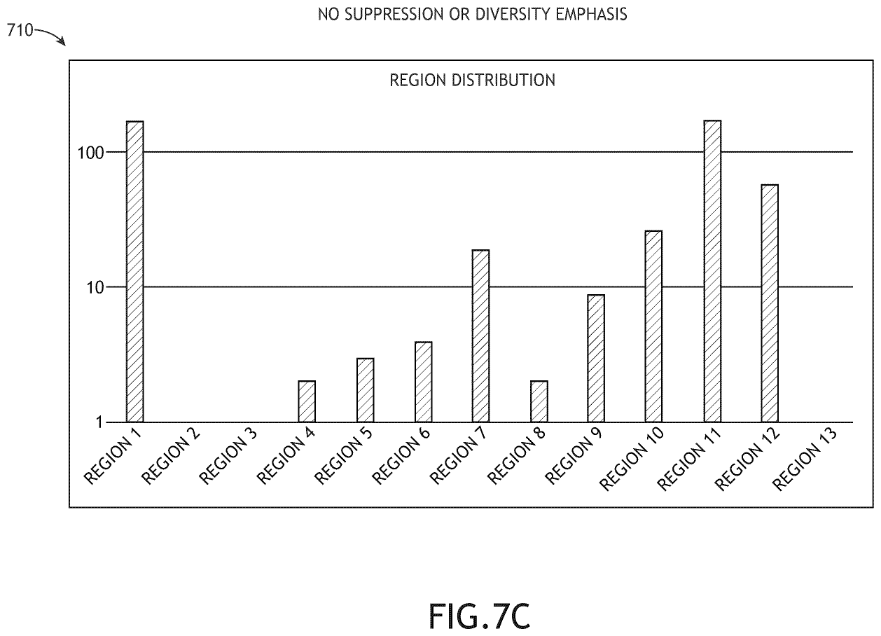

FIGS. 7A-14C depict various sampling schemes generated with different weighting schemes as defined by the diversity weights, a global diversity weight related to a strength of diversity weighting, and a global suppression weight related to suppression of large defects. In particular, each of FIGS. 7A-14C include a die heat map indicating dies with locations included in the review sampling map, an observed class diversity (e.g., a percentage of defects falling into the probable classes of high-confidence DOIs, low-confidence DOIs, high-confidence nuisances, and low-confidence nuisances), a raw strength histogram for observed defects based on sample score, a suppressed rank histogram including suppressed defects based on sample score, and a region distribution plot depicting a number of defect events falling into 13 predefined regions of a sample 108. Further, in cases that include a non-zero weight for class diversity, the sub-weights of four probable classes are set to 40% high-confidence DOIs, 30% low-confidence DOIs, 5% high-confidence nuisances, and 25% low-confidence nuisances.

FIGS. 7A-7C illustrate defect analysis results for a case where no suppression or diversity emphasis is selected (e.g., in step 206), in accordance with one or more embodiments of the present disclosure. FIG. 7A depicts a die heat map 702 and an observed class diversity 704. The die heat map 702 shows a high concentration of sampled locations in a few dies, indicating an uneven distribution of review points across the sample 108. The observed class diversity 704 reveals that a large portion of the sampled locations are high-confidence nuisances, with 335 out of 500 total sampled locations falling into this category. FIG. 7B illustrates a raw strength rank histogram 706 and a suppressed event rank histogram 708, where nearly all defect events are strong (e.g., having low sample scores) and many defect events with high defect scores are suppressed (e.g., not included in the sampling map). FIG. 7C shows a region distribution 710 across multiple regions. The region distribution 710 displays an uneven distribution of sampled locations across different regions of the sample 108, with some regions having over 100 locations and some regions not included in the review sampling map.

In this configuration with no suppression or diversity emphasis, the review sampling map may not efficiently review critical DOIs. The high concentration of sampled locations in a few dies, as shown in the die heat map 702, combined with the large proportion of high-confidence nuisances in the observed class diversity 704, suggests that the review resources may not be optimally allocated. This distribution may result in missed opportunities to capture a diverse range of critical DOIs across different regions and classes.

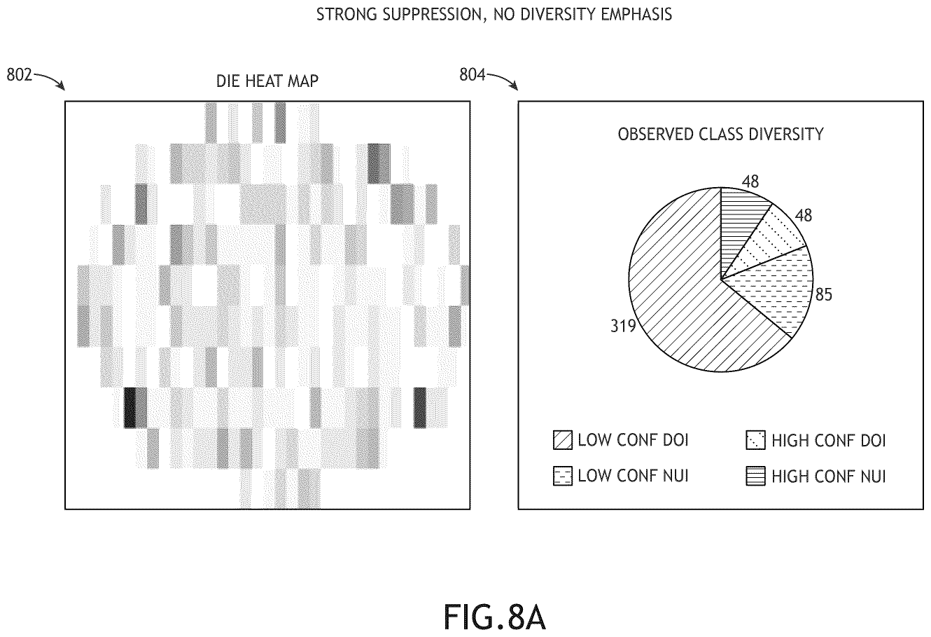

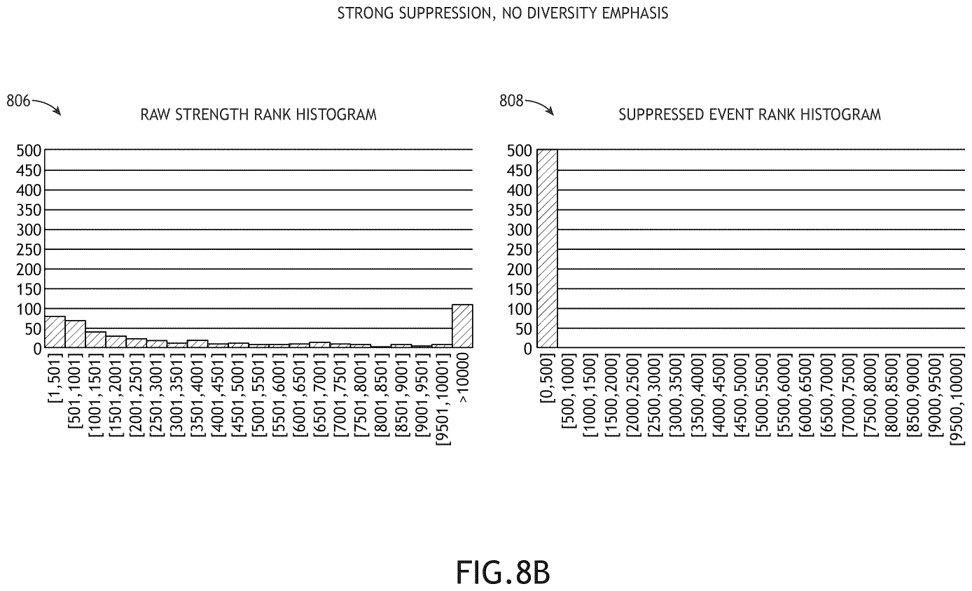

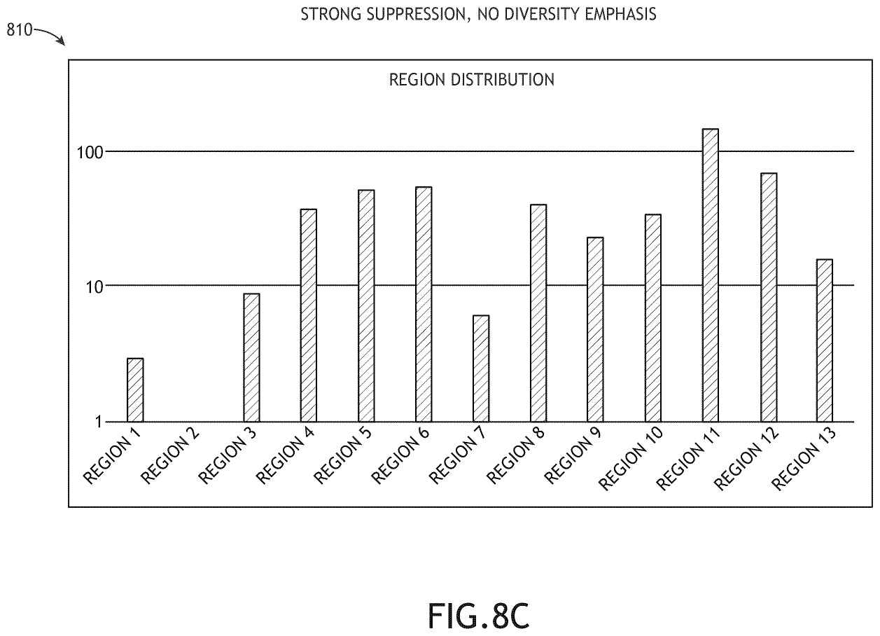

FIGS. 8A-8C illustrate defect analysis results for a case where strong suppression and no diversity emphasis are selected (e.g., in step 206), in accordance with one or more embodiments of the present disclosure. These figures correspond to a configuration with a global suppression weight of 100% and a global diversity weight of 0. In this configuration, the die heat map 802 displays a more distributed pattern of sampled locations across the sample 108 compared to the case with no suppression or diversity emphasis. The raw strength rank histogram 806 shows a broader distribution of defect events across different rank values, indicating that the strong suppression has affected the ranking of defects. The suppressed event rank histogram 808 displays a concentration of events in the lowest rank bin, suggesting that many events with higher ranks have been suppressed. The region distribution 810 also shows a more uniform distribution of sampled locations across different regions of the sample 108 compared to the case with no suppression or diversity emphasis. This indicates that the strong suppression has led to a more diverse sampling across regions.

However, the observed class diversity 804 reveals that a significant portion of the sampled locations are still high-confidence nuisances, suggesting that suppression alone may not be sufficient to optimally prioritize defects of interest (DOIs) in the review sampling map.

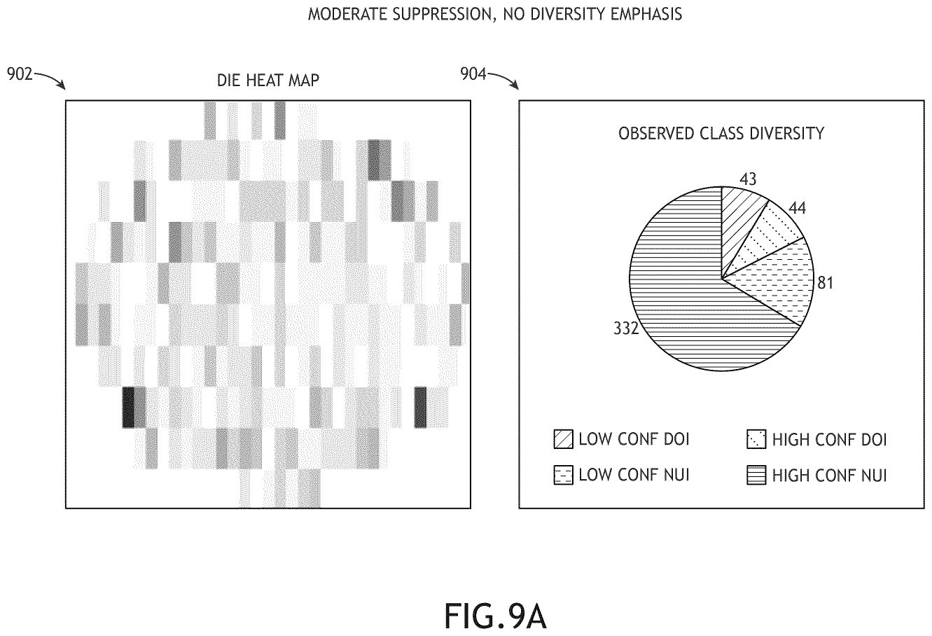

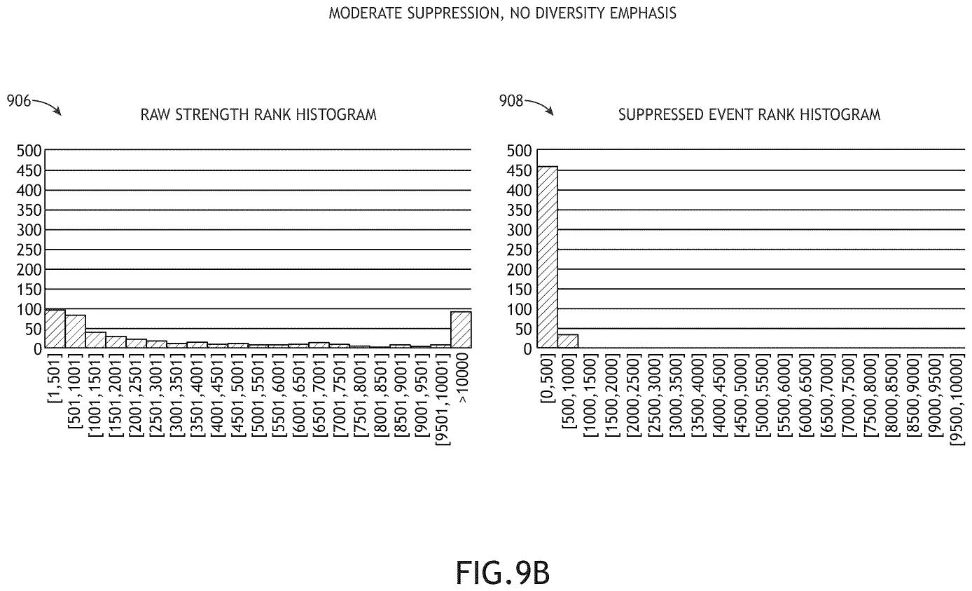

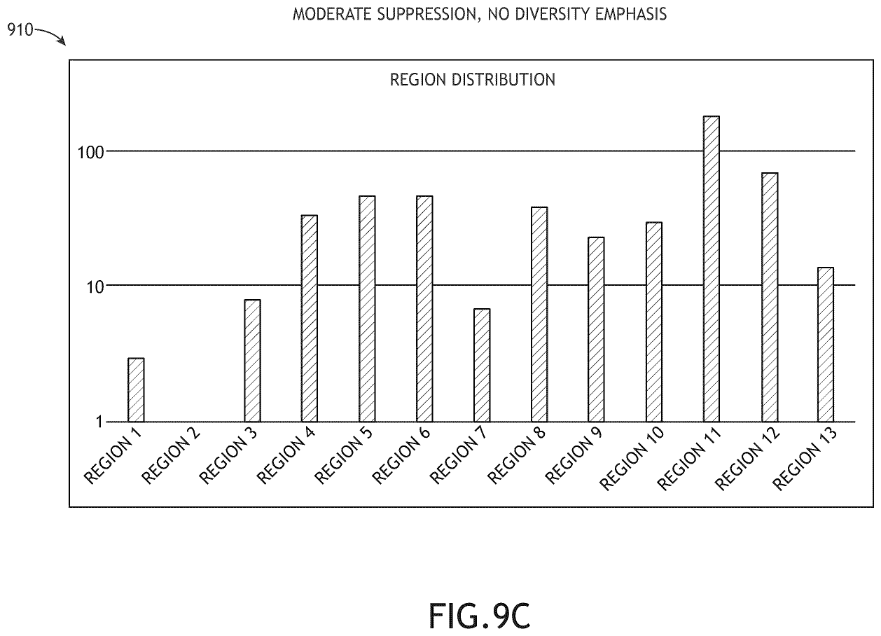

FIGS. 9A-9C illustrate defect analysis results for a case where moderate suppression (e.g., a global suppression weight of 70%) and no diversity emphasis are selected (e.g., in step 206), in accordance with one or more embodiments of the present disclosure. FIG. 9A depicts a die heat map 902 and an observed class diversity 904. FIG. 9B illustrates a raw strength rank histogram 906 and a suppressed event rank histogram 908, showing the distribution of defect events before and after suppression. FIG. 9C displays a region distribution 910 across multiple regions. The sampling results are similar to FIGS. 8A-8C, though slightly less pronounced due to the decreased global suppression weight.

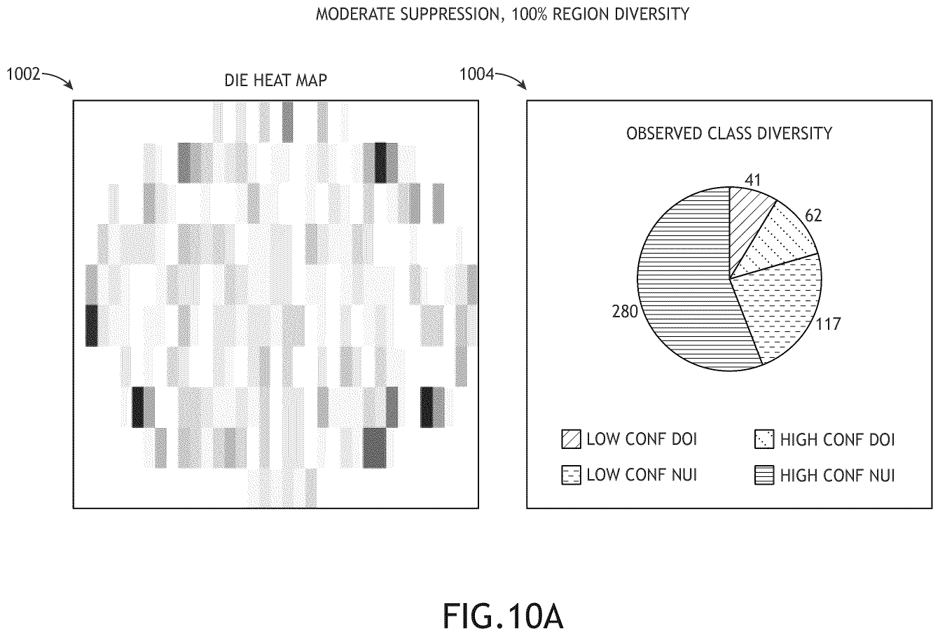

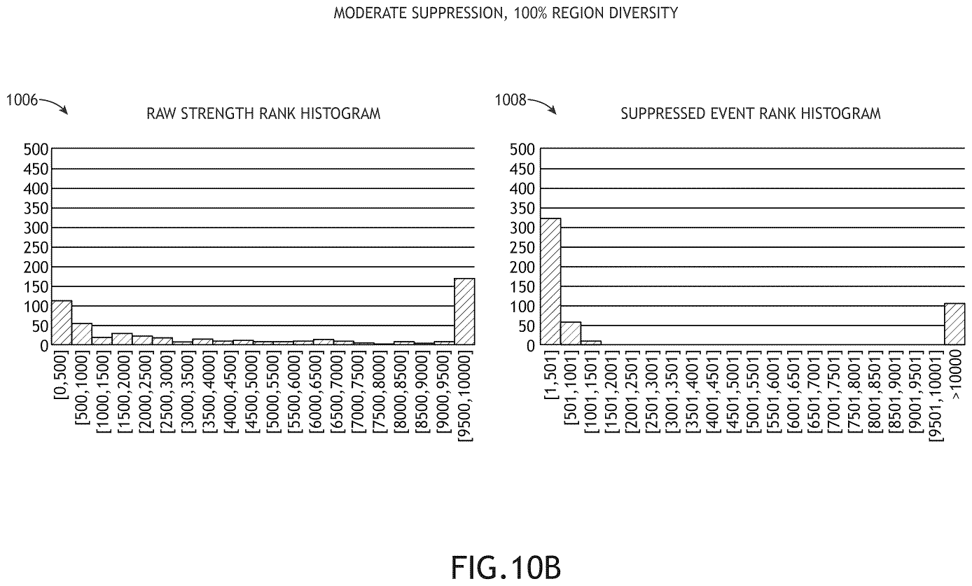

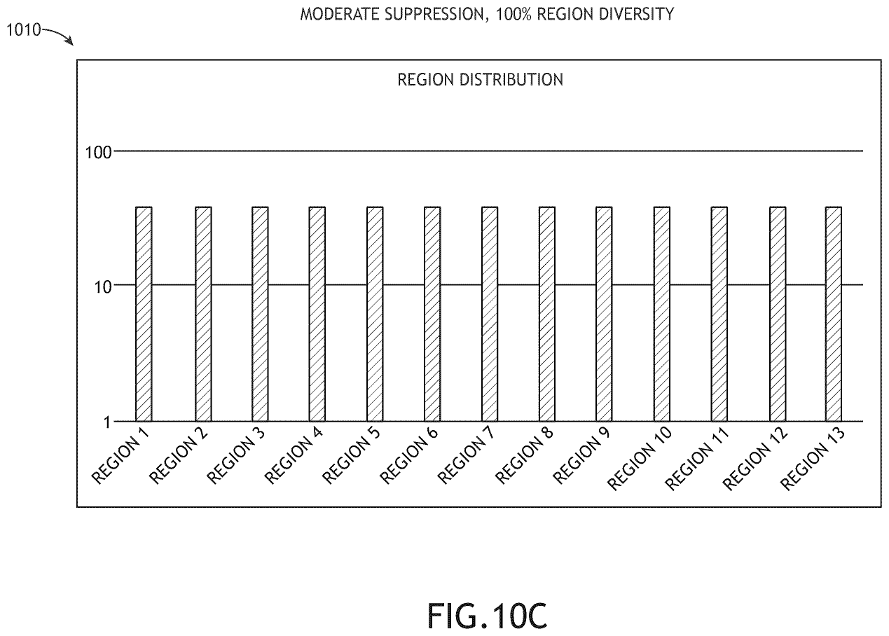

FIGS. 10A-10C illustrate defect analysis results for a case where moderate suppression and 100% region diversity are selected (e.g., in step 206), in accordance with one or more embodiments of the present disclosure. These figures illustrate a weighting scheme with moderate suppression (e.g., a global suppression weight of 70%) and 100% region diversity (e.g., a diversity enhancement factor of 100% and a region diversity sub-weight of 100%). FIG. 10A depicts a die heat map 1002 and an observed class diversity 1004. FIG. 10B illustrates a raw strength rank histogram 1006 and a suppressed event rank histogram 1008, showing the distribution of defect events before and after suppression. FIG. 10C displays a region distribution 1010 across multiple regions.

The region distribution 1010 in FIG. 10C demonstrates completely uniform sampling across the different regions. In this configuration, all regions show equal representation, indicating that the 100% region diversity weighting has effectively distributed the sampled locations evenly across all predefined regions of the sample 108. Compared to FIGS. 7A-7C, the die heat map 1002 in FIG. 10A displays a more distributed pattern of sampled locations across the sample 108, suggesting more diverse sampling. The raw strength rank histogram 1006 and the suppressed event rank histogram 1008 in FIG. 10B also indicates a broader distribution of defect events across different rank values, further supporting the increased diversity in sampling compared to the case with no suppression or diversity emphasis.

The observed class diversity 1004 in FIG. 10A reveals that fewer high-confidence nuisances are sampled in this configuration relative to FIGS. 9A-9C. However, the difference in sampling may be associated with a relative increase in low-confidence nuisances, which only marginally improves the quality of the review sampling map.

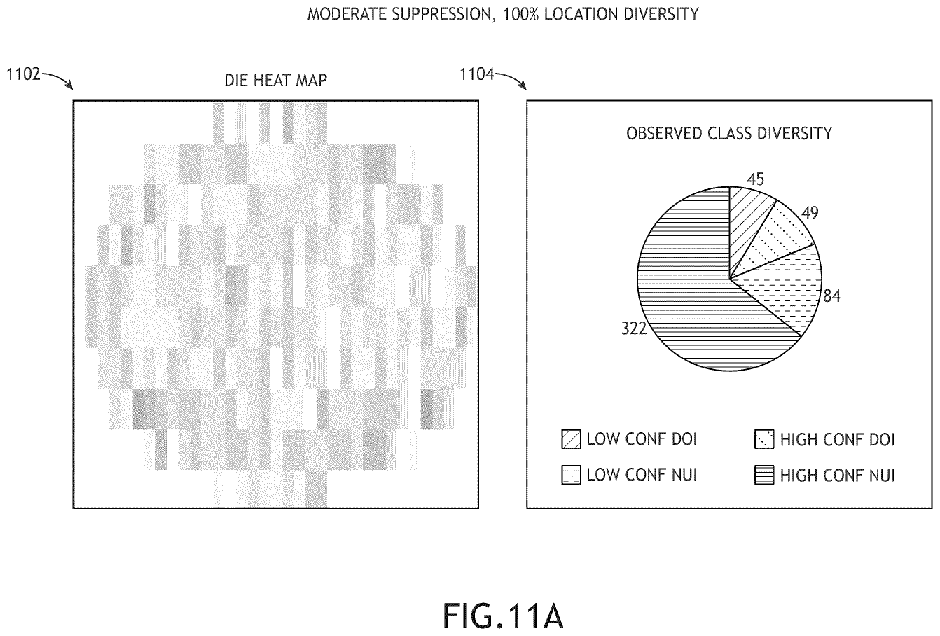

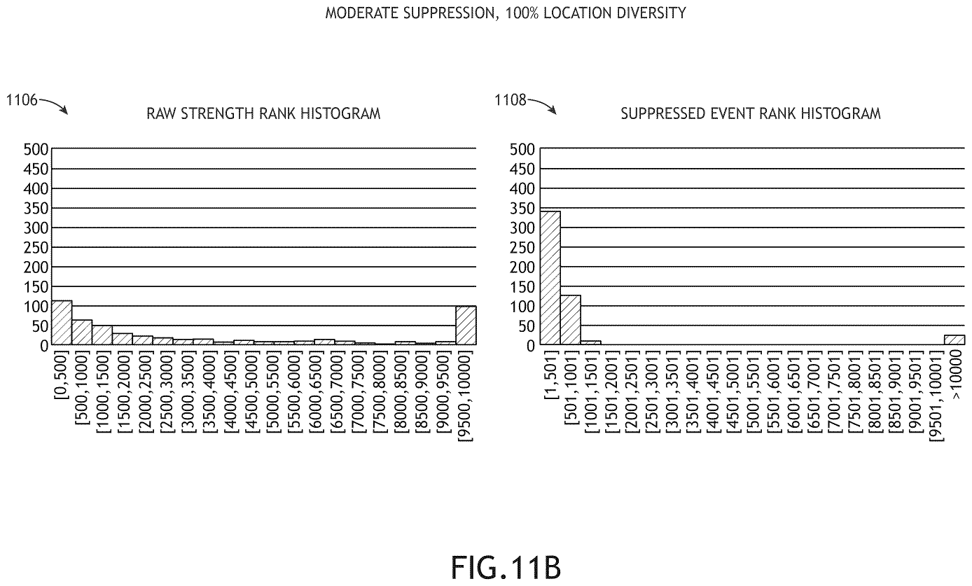

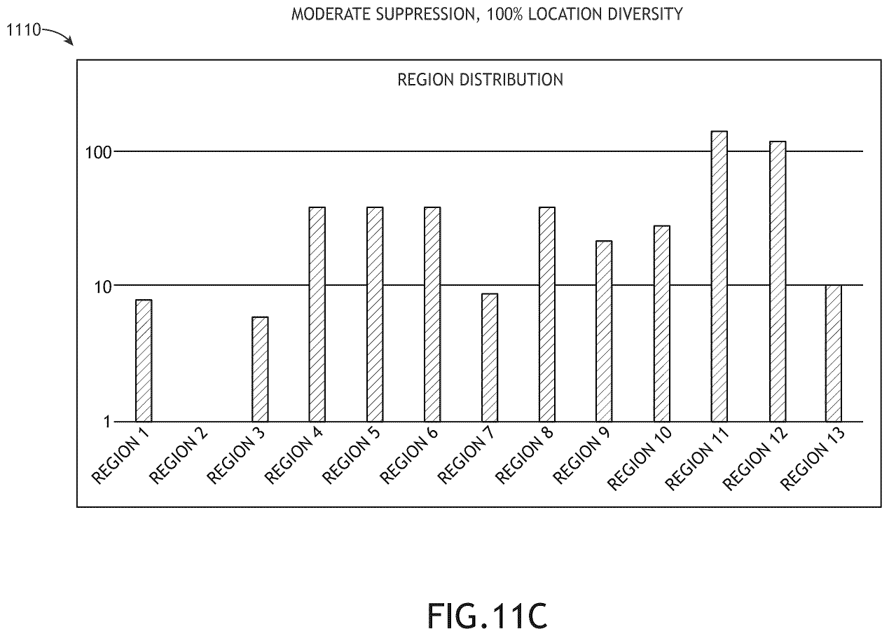

FIGS. 11A-11C illustrate defect analysis results for a case where moderate suppression and 100% location diversity are selected (e.g., in step 206), in accordance with one or more embodiments of the present disclosure. These figures correspond to a configuration with moderate suppression (e.g., a global suppression weight of 70%) and 100% location diversity (e.g., a global diversity weight of 100% and a location diversity sub-weight of 100%). FIG. 11A depicts a die heat map 1102 and an observed class diversity 1104. FIG. 11B illustrates a raw strength rank histogram 1106 and a suppressed event rank histogram 1108, showing the distribution of defect events before and after suppression. FIG. 11C displays a region distribution 1110 across multiple regions.

In this configuration, the die heat map 1102 displays a substantially uniform distribution of sampled locations across the sample 108, indicating that the 100% location diversity weighting has effectively distributed the sampled locations across different areas of the sample 108. However, the observed class diversity 1104 in FIG. 11A reveals a distribution of defect classes that is similar to the previous configurations with a substantial number of high-confidence nuisances.

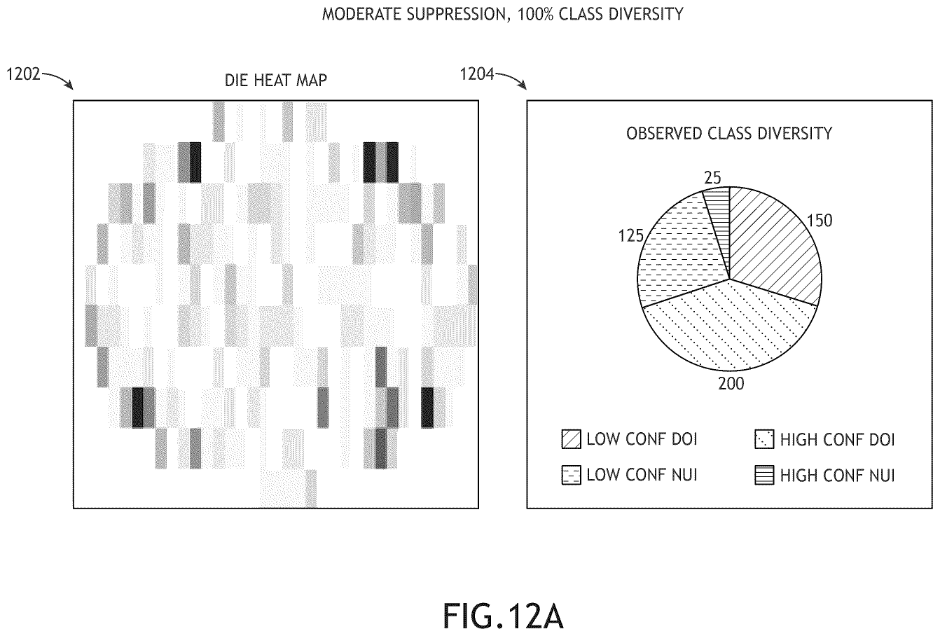

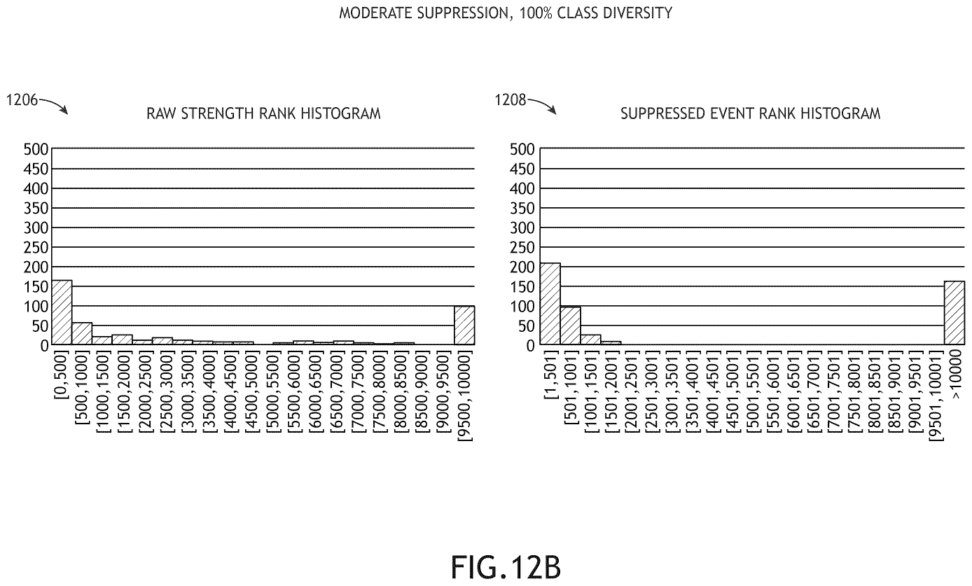

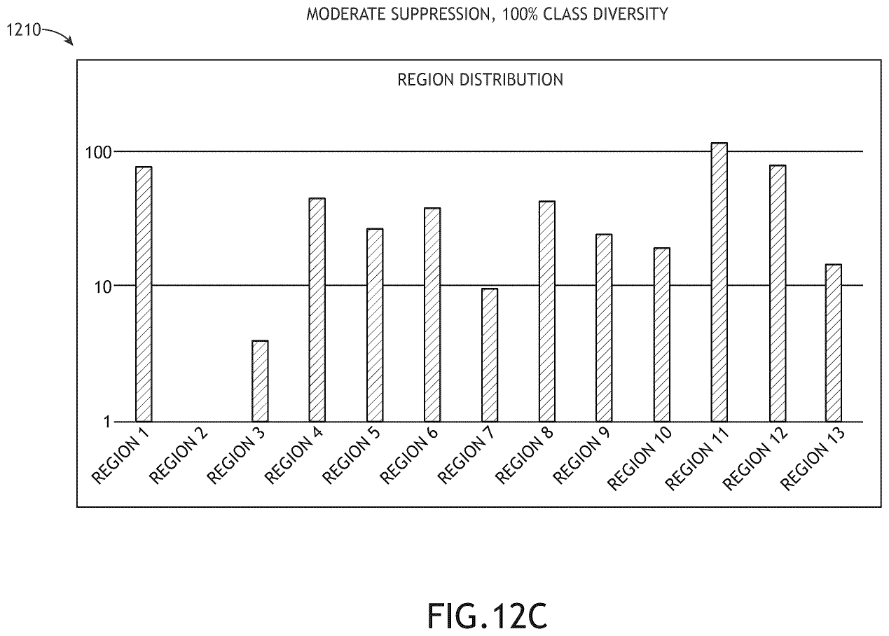

FIGS. 12A-12C illustrate defect analysis results for a case where moderate suppression and 100% class diversity are selected (e.g., in step 206), in accordance with one or more embodiments of the present disclosure. These figures correspond to a configuration with moderate suppression (e.g., a global suppression weight of 70%) and 100% class diversity (e.g., a global diversity weight of 100% and a class diversity sub-weight of 100%).

FIG. 12A depicts a die heat map 1202 and an observed class diversity 1204. FIG. 12B illustrates a raw strength rank histogram 1206 and a suppressed event rank histogram 1208, showing the distribution of defect events before and after suppression. FIG. 12C displays a region distribution 1210 across multiple regions. In this configuration, the observed class diversity 1204 in FIG. 12A reveals a distribution of defect classes that closely matches the target ratios specified by the class diversity sub-weights. In some cases, the observed class diversity 1204 may show approximately 40% high-confidence DOIs, 30% low-confidence DOIs, 5% high-confidence nuisances, and 25% low-confidence nuisances. This distribution may indicate that the 100% class diversity weighting effectively prioritizes the sampling of defects according to the specified class ratios. The die heat map 1202 displays a less uniform distribution of sampled locations across the sample 108 compared to previous configurations, which may suggest a concentration of critical defects in certain dies on the sample 108.

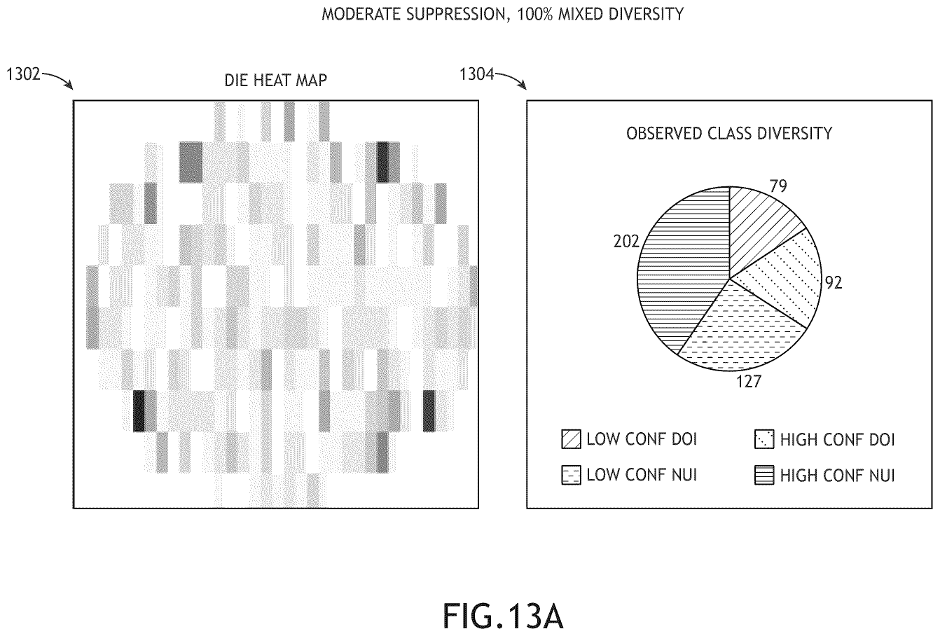

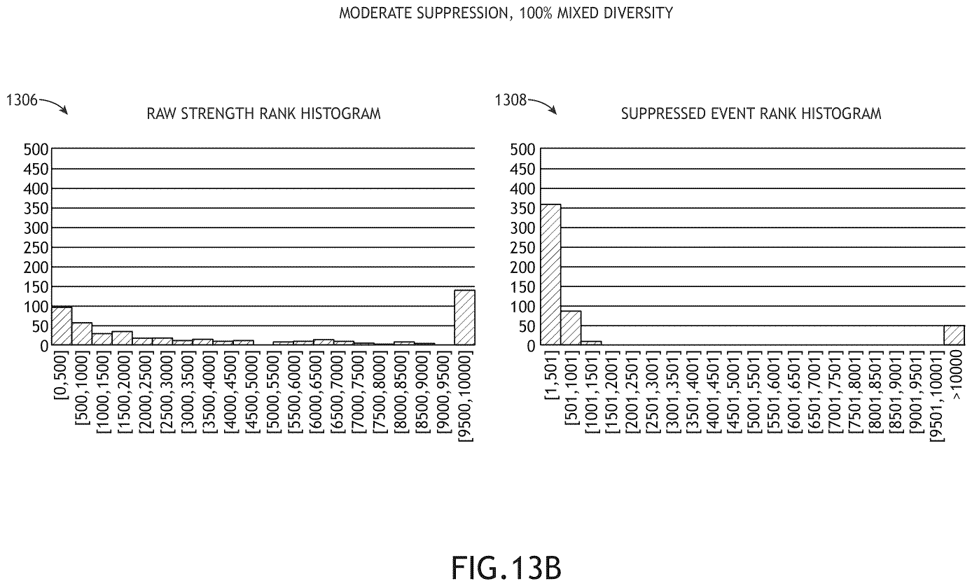

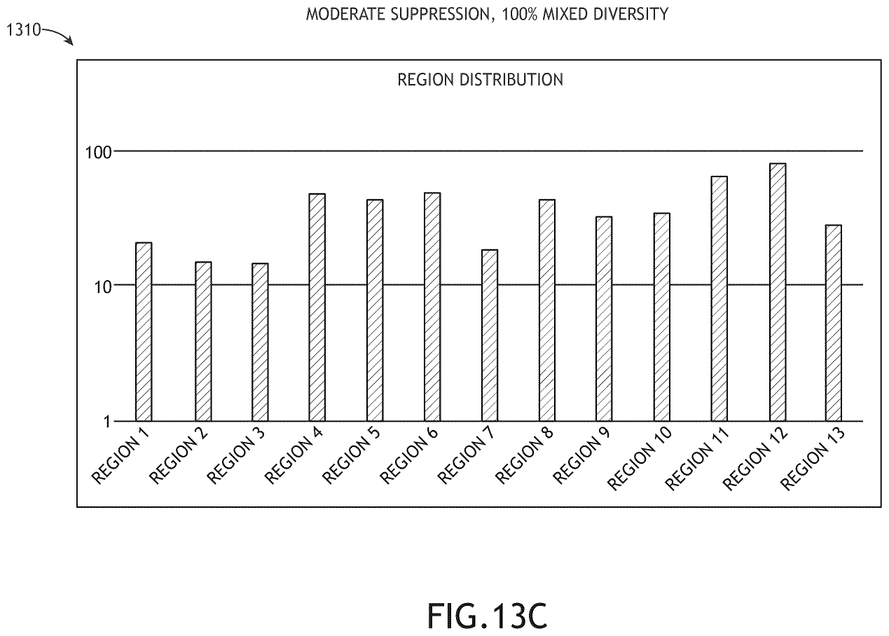

FIGS. 13A-13C illustrate defect analysis results for a case where moderate suppression and 100% mixed diversity are selected (e.g., in step 206), in accordance with one or more embodiments of the present disclosure. These figures correspond to a configuration with moderate suppression (e.g., a global suppression weight of 70%) and strong diversity emphasis (e.g., a global diversity weight of 100%), with diversity weights distributed as 40% for region, 30% for location, and 30% for class. FIG. 13A depicts a die heat map 1302 and an observed class diversity chart 1304. FIG. 13B illustrates a raw strength rank histogram 1306 and a suppressed event rank histogram 1308, showing the distribution of defect events before and after suppression. FIG. 13C depicts a region distribution 1310 across multiple regions.

In this configuration, the observed class diversity chart 1304 in FIG. 13A reveals a relatively balanced distribution of defect classes. The distribution may not precisely match the target ratios specified by the class diversity sub-weights, but may show a more balanced representation of different defect classes compared to previous configurations. The region distribution 1310 in FIG. 13C also demonstrates a relatively balanced distribution of sampled locations across different regions of the sample 108 based on the inclusion of some region diversity weighting. Further, the die heat map 1302 shows a fairly balanced distribution across the sample 108, though hot spots exist for certain dies based on the substantial sampling of critical DOIs in those dies.

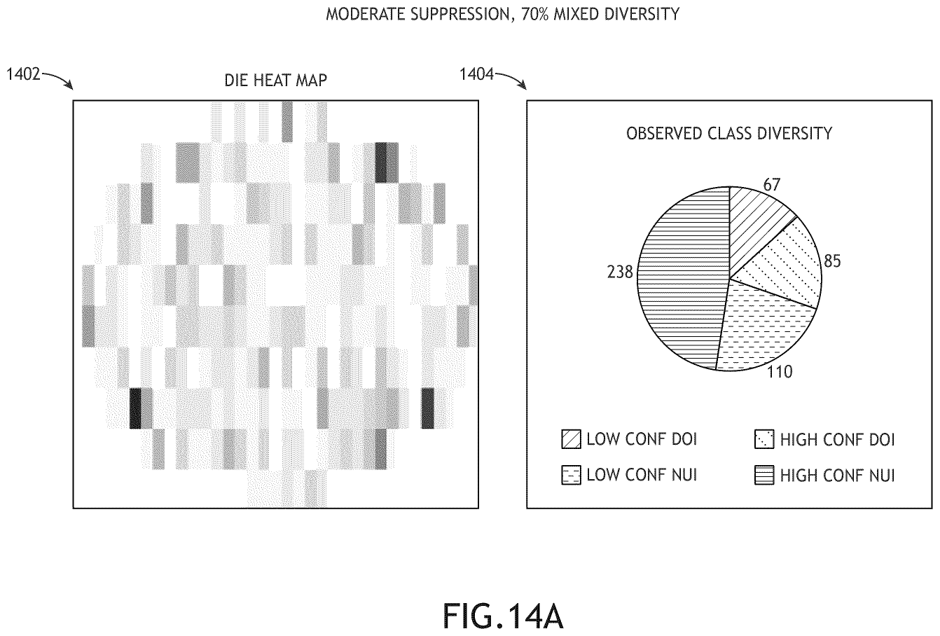

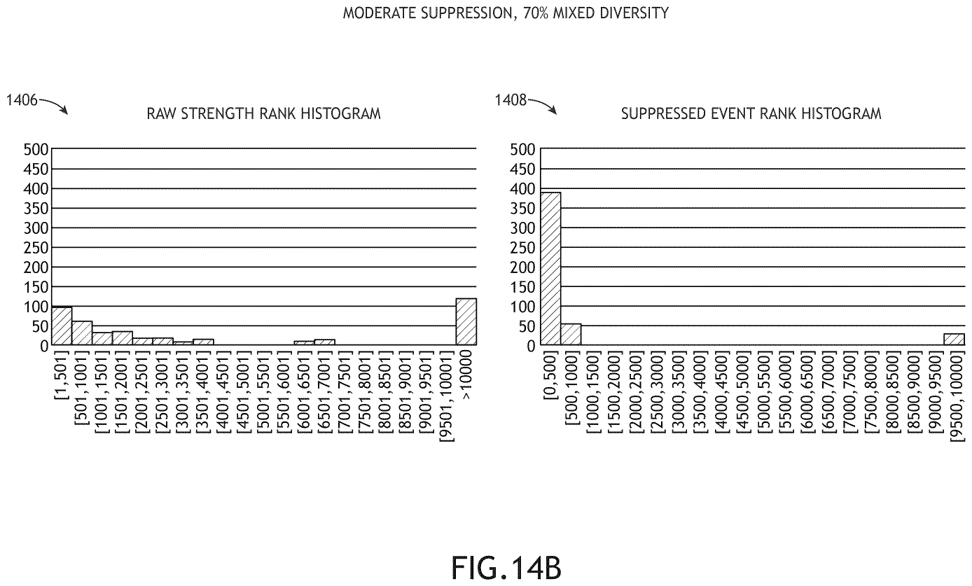

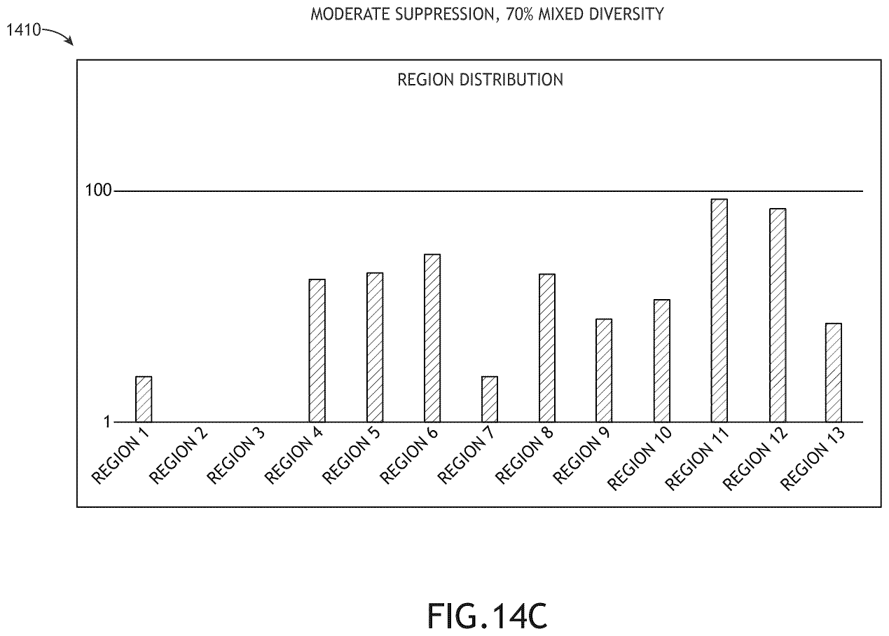

FIGS. 14A-14C illustrate defect analysis results for a case where moderate suppression and 70% mixed diversity are selected (e.g., in step 206), in accordance with one or more embodiments of the present disclosure. These figures correspond to a configuration with moderate suppression (e.g., a global suppression weight of 70%) and moderate diversity emphasis (e.g., a global diversity weight of 70%), with diversity weights distributed as 40% for region, 30% for location, and 30% for class. FIG. 14A depicts a die heat map 1402 and an observed class diversity 1404. FIG. 14B illustrates a raw strength rank histogram 1406 and a suppressed event rank histogram 1408, showing the distribution of defect events before and after suppression. FIG. 14C displays a region distribution 1410 across multiple regions. The results are similar to those shown in FIGS. 13A-13C, but with less region uniformity and increased numbers of high-confidence nuisances, which may be attributed to the weaker diversity emphasis.

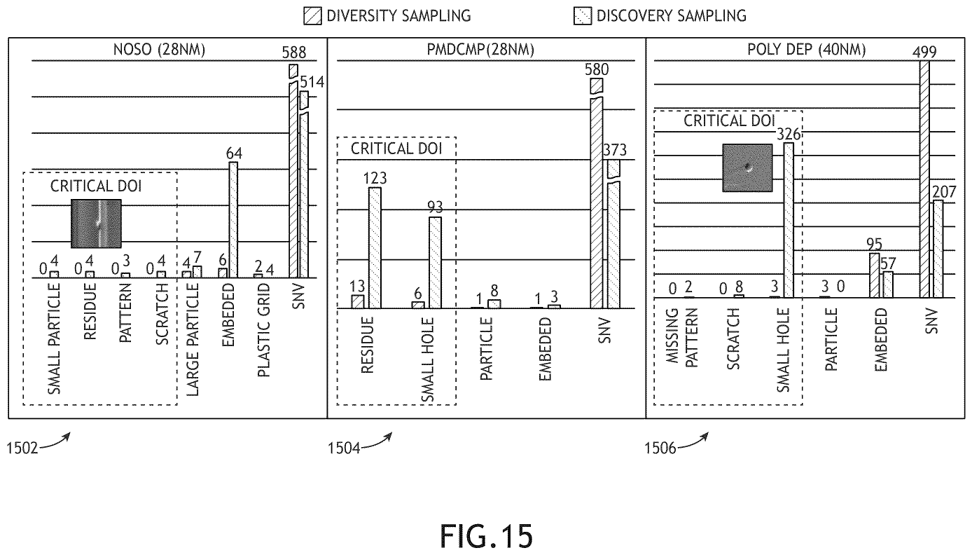

FIG. 15 illustrates defect sampling distribution plots across different technologies, in accordance with one or more embodiments of the present disclosure. FIG. 15 includes a plot 1502, a plot 1504, and a plot 1506 showing defect sampling distributions for NOSO (28 nm), PMDCMP (28 nm), and Poly Dep (40 nm) fabrication, respectively.

The plot 1502, the plot 1504, and the plot 1506 compare defect sampling results between traditional diversity sampling and discovery sampling as disclosed herein across various defect categories. In the plot 1502 for NOSO (28 nm) technology, discovery sampling demonstrates substantially higher sampling rates for critical defects of interest (DOIs) such as small particles and residues compared to diversity sampling. The plot 1504 for PMDCMP (28 nm) technology shows similar trends, with discovery sampling capturing more critical DOIs like small holes and embedded defects while suppressing non-critical defects. In the plot 1506 for Poly Dep (40 nm) technology, discovery sampling again exhibits improved detection of critical DOIs such as missing patterns and scratches.

Across all of the device and defect types represented in the plot 1502, the plot 1504, and the plot 1506, discovery sampling consistently enables higher review rates for critical DOIs while simultaneously suppressing review of non-critical DOIs and nuisances when compared to diversity sampling. The advantages are particularly evident for smaller defect types that may be challenging to detect, such as small particles, small holes, and missing patterns. The discovery sampling method may provide a more targeted approach to defect review, potentially improving the efficiency and effectiveness of the inspection process across different semiconductor manufacturing technologies and defect types.

Referring again to FIG. 2, additional steps of the method 200 are described.

In embodiments, the method 200 includes a step 210 of reviewing the set of review locations on the one or more samples with a review tool 110.

For example, in step 210, the review tool 110 may be directed to review the set of review locations identified in the review sampling map generated in step 208. In some cases, the review controller 114 may receive instructions from the processing controller 116 specifying the review locations. The review controller 114 may then control the review sub-system 112 to analyze the specified locations on the one or more samples 108. The review sub-system 112 may utilize high-resolution imaging techniques to capture detailed information about the potential defects at the specified review locations. In cases where the review tool 110 includes a scanning electron microscope (SEM), the review sub-system 112 may generate high-resolution electron microscope images of the review locations.

The review data may provide detailed information about the actual characteristics of defects, which may be used to validate or improve the classification of defects performed in earlier steps of the method 200. In some cases, the review data generated by the review tool 110 may be used as ground truth data for training or refining defect classification models (e.g., nuisance optimization models, or the like). For example, the review data may be used as training data for a defect classification model such as, but not limited to, a random forest model.

The review data from the review tool 110 may be sent back to the processing controller 116 for further analysis. In some cases, the processing controller 116 may use the review data to generate or refine an inspection recipe for future inspections of similar samples. The inspection recipe may incorporate optimized detection parameters and classification criteria based on the insights gained from the review process.

In some embodiments, the method 200 may include an additional step, not explicitly shown in FIG. 2, of inspecting one or more additional samples with the inspection tool 102 using the inspection recipe generated or refined based on the review data. This step may involve applying the optimized detection parameters and classification criteria from the inspection recipe to new samples, potentially from the same or similar manufacturing processes. The inspection tool 102 may utilize the refined inspection recipe to more accurately identify and classify defects on these additional samples, leveraging the insights gained from the previous discovery sampling and review processes.

Referring generally to FIGS. 1A-15, the systems and methods disclosed herein may used to generate an inspection recipe for any type of inspection tool 102 using review from any type of review tool 110, along with any associated inspection or review models.

FIG. 1B illustrates a block diagram of an inspection sub-system 104, in accordance with one or more embodiments of the present disclosure. For example, the inspection sub-system 104 may be a non-limiting illustration of a darkfield optical sub-system suitable for implementing the step 202.

In embodiments, the inspection sub-system 104 includes an illumination source 118 configured to generate an illumination beam. The illumination source 118 may include any type of illumination source known in the art suitable for generating an optical illumination beam. The illumination beam may have any spectrum such as, but not limited to, extreme ultraviolet (EUV) wavelengths, ultraviolet (UV) wavelengths, visible wavelengths, or infrared (IR) wavelengths. Further, the illumination source 118 may be a broadband source, a narrowband source, and/or a tunable source.

In embodiments, the illumination source 118 includes a broadband plasma (BBP) illumination. In this configuration, the illumination beam may include radiation emitted by a plasma. For example, a BBP illumination source 118 may include, but is not required to include, one or more pump sources (e.g., one or more lasers) configured to focus into the volume of a gas, causing energy to be absorbed by the gas in order to generate or sustain a plasma suitable for emitting radiation. Further, at least a portion of the plasma radiation may be utilized as the illumination beam.

In embodiments, the illumination source 118 may include one or more lasers. For instance, the illumination source 118 may include any laser system known in the art capable of emitting radiation in the infrared, visible, or ultraviolet portions of the electromagnetic spectrum.

The illumination source 118 may further produce an illumination beam having any temporal profile. For example, the illumination source 118 may produce continuous-wave (CW) illumination beam, pulsed illumination beam, or modulated illumination beam. Additionally, the illumination beam may be delivered from the illumination source 118 via free-space propagation or guided light (e.g., an optical fiber, a light pipe, or the like).

Although not shown, the inspection sub-system 104 may include various components to direct the illumination beam to the sample 108 such as, but not limited to, mirrors, lenses (e.g., lens 120), diverters, filters (e.g., spatial and/or temporal filters), diffusers, homogenizers, apodizers, beamsplitters, or the like. Further, such components may be reflective elements or transmissive elements.

In embodiments, sample 108 is disposed on a stage assembly 122 to facilitate movement of sample 108. Stage assembly 122 may include any actuators known in the art including, but not limited to, an X-Y stage, an R-θ stage, a tip/tilt stage, or the like. Further, the stage assembly 122 is capable of adjusting the height of sample 108 during inspection or imaging to maintain focus on the sample 108.

In embodiments, inspection sub-system 104 includes one or more detection channels. The one or more detection channels may include one or more detectors configured to collect illumination scattered from the sample 108 and acquire images of the sample 108. For example, as shown in FIG. 1B, inspection sub-system 104 may include a first detection channel 124a including a first detector 126a, a second detection channel 124b including a second detector 126b, and a third detection channel 124c including a third detector 126c. In the configuration of FIG. 1B, the first detector 126a, the second detector 126b, and the third detector 126c are positioned to generate darkfield images based on light that is scattered and/or diffracted by the sample 108, where each detector generates an image with light from a different range of collection angles.

The one or more detectors (e.g., detectors 124a-124c) may include any type of sensor suitable for capturing scattered light from the sample 108 such as, but not limited to, complementary metal-oxide-semiconductor (CMOS) sensors, charge-coupled devices (CCDs), time delay integration (TDI) sensors, avalanche photodiodes (APDs), photomultiplier tubes (PMTs), or hybrid detectors combining multiple technologies.

Although not shown, the inspection tool 102 may include one or more optical elements configured to collect illumination scattered from the sample 108 and direct the illumination to the one or more detectors. The one or more optical elements may include any optical elements known in the art including, but not limited to, mirrors, lenses, diverters, filters (e.g., spatial and/or temporal filters), diffusers, homogenizers, apodizers, beamsplitters, or the like.

While FIG. 1B illustrates an inspection sub-system 104 including three detectors configured to acquire patch images along three scattering angles, this is not to be regarded as a limitation of the present disclosure, unless noted otherwise herein. In this regard, it is contemplated that inspection sub-system 104 may be arranged in any configuration including, but not limited to, a one-detection-channel configuration, a two-detection-channel configuration, a three-detection-channel configuration, a five-detection-channel configuration, and the like. Comparisons between various channel configurations will be discussed in further detail herein.

FIG. 1C illustrates a block diagram of a review sub-system 112, in accordance with one or more embodiments of the present disclosure. For example, FIG. 1C may depict a non-limiting example of a SEM review sub-system 112.

In embodiments, the review sub-system 112 includes a particle source 128 to generate a particle beam 130. The particle source 128 may include any particle source known in the art suitable for generating a particle beam 130. For example, the particle source 128 may include, but is not limited to, an electron gun or an ion gun. In another embodiment, the particle source 128 is configured to provide a particle beam with a tunable energy. For example, a particle source 128 including an electron source may, but is not limited to, provide an accelerating voltage in the range of 0.1 kV to 30 kV. As another example, a particle source 128 including an ion source may, but is not required to, provide an ion beam with an energy in the range of 1 to 50 keV.

In another embodiment, the particle control elements 132 includes one or more particle focusing elements. For example, the one or more particle focusing elements may include, but are not limited to, a single particle focusing element or one or more particle focusing elements forming a compound system. In another embodiment, the one or more particle focusing elements include an objective lens configured to direct the particle beam 130 to the sample 108. Further, the one or more particle focusing elements may include any type of electron lenses known in the art including, but not limited to, electrostatic, magnetic, uni-potential, or double-potential lenses. It is noted herein that the description of a voltage contrast imaging inspection system as depicted in FIG. 1C and the associated descriptions above are provided solely for illustrative purposes and should not be interpreted as limiting. For example, the review sub-system 112 may include any excitation source known in the art suitable for generating review data on a sample 108. In another embodiment, the review sub-system 112 includes two or more particle beam sources (e.g., electron beam sources or ion beam sources) for the generation of two or more particle beams. In a further embodiment, the review sub-system 112 may include one or more components (e.g., one or more electrodes) configured to apply one or more voltages to one or more locations of the sample 108. In this regard, the review sub-system 112 may generate voltage contrast imaging data.

In another embodiment, the review sub-system 112 includes one or more particle detectors 134 to image or otherwise detect particles emanating from the sample 108. In one embodiment, the particle detector 134 includes an electron collector (e.g., a secondary electron collector, a backscattered electron detector, or the like). In another embodiment, the particle detector 134 includes a photon detector (e.g., a photodetector, an x-ray detector, a scintillating element coupled to photomultiplier tube (PMT) detector, or the like) for detecting electrons and/or photons from the sample surface.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An inspection system comprising:
one or more controllers including one or more processors configured to execute program instructions causing the one or more processors to:
receive inspection data for one or more samples from an inspection tool;
assign sample scores to defect events from a hot scan associated with the inspection data;
select values of diversity weights for one or more diversity factors;
generate a review sampling map based on the sample scores and the diversity weights, wherein the review sampling map includes a set of review locations on the one or more samples to review with a review tool, wherein the diversity weights control impacts of the one or more diversity factors on the review sampling map; and
direct the review tool to review the set of review locations on the one or more samples.

2. The inspection system of claim 1, wherein the sample scores are proportional to outputs of an automated sensitivity tuner that selects values of detection parameters of a detection model to achieve a desired detection rate of probable defects relative to total defect count, wherein the detection model identifies the defect events from the inspection data by comparing the inspection data to reference data and applying thresholds associated with the detection parameters.

3. The inspection system of claim 2, wherein the automated sensitivity tuner includes an unsupervised model to assign outlier rankings to the defect events from the hot scan, wherein the sample scores are proportional to the outlier rankings.

4. The inspection system of claim 3, wherein the unsupervised model generates the outlier rankings by:
generating one or more attribute plots with the defect events from the hot scan associated with the inspection data, wherein axes of a particular one of the one or more attribute plots include two or more of the detection parameters; and
assigning the outlier rankings to the defect events based on the one or more attribute plots.

5. The inspection system of claim 4, wherein the outlier rankings are associated with a defect density in the one or more attribute plots.

6. The inspection system of claim 4, wherein the outlier ranking for a particular defect event is associated with one or more distances of the particular defect event from one or more clusters identified in the one or more attribute plots.

7. The inspection system of claim 2, wherein the automated sensitivity tuner includes a supervised model, wherein the sample scores are proportional to an output of the supervised model.

8. The inspection system of claim 1, wherein generating the review sampling map based on the sample scores and the diversity weights comprises:
applying the diversity weights to the sample scores to generate diversity-weighted sample scores; and
generating the review sampling map based on the diversity-weighted sample scores.

9. The inspection system of claim 1, wherein generating the review sampling map based on the sample scores and the diversity weights comprises:
dividing a number of locations in the review sampling map into multiple bins representing different diversity factors; and
filling the bins based on the sample scores of the defect events.

10. The inspection system of claim 1, wherein at least one of the one or more diversity factors comprises:
diversity of locations across a sample of the one or more samples.

11. The inspection system of claim 1, wherein at least one of the one or more diversity factors comprises:
diversity of predefined regions associated with the one or more samples.

12. The inspection system of claim 1, wherein the program instructions further cause the one or more processors to:
label the defect events into two or more defect classes with a neural network model, wherein the neural network model is trained on defect data associated with the two or more defect classes, wherein at least one of the one or more diversity factors comprises class diversity associated with the two or more defect classes.

13. The inspection system of claim 12, wherein the neural network model is trained on data from at least one of multiple layers or multiple patterns.

14. The inspection system of claim 1, wherein selecting the values of the diversity weights for the one or more diversity factors comprises:
selecting the values of the diversity weights for two or more diversity factors.

15. The inspection system of claim 1, wherein the values of the diversity weights further include a global diversity weight controlling a global strength of multiple diversity factors.

16. The inspection system of claim 1, wherein at least one of the one or more diversity factors comprises:
a suppression factor that de-weights undesired defects.

17. The inspection system of claim 16, wherein the undesired defects include defects larger than a selected size.

18. The inspection system of claim 16, wherein the undesired defects include defects with known review signatures.

19. The inspection system of claim 16, wherein at least one of the one or more diversity factors further include a global suppression weight controlling a global strength of multiple suppression factors.

20. The inspection system of claim 1, wherein the program instructions are further configured to cause the one or more processors to generate an inspection recipe based on review data from the review tool associated with the set of review locations.

21. The inspection system of claim 1, wherein selecting the values of the diversity weights for the one or more diversity factors comprises:
providing a user with diversity controls associated with the diversity weights; and
receiving the values of the diversity weights based on the diversity controls.

22. The inspection system of claim 1, wherein selecting the values of the diversity weights for the one or more diversity factors comprises:
selecting the values of the diversity weights for the one or more diversity factors from a set of default values.

23. An inspection system comprising:
an inspection sub-system;
a review tool; and
one or more controllers including one or more processors configured to execute program instructions causing the one or more processors to:
receive inspection data for one or more samples from an inspection tool;
assign sample scores to defect events from a hot scan associated with the inspection data;
select values of diversity weights for one or more diversity factors;
generate a review sampling map based on the sample scores and the diversity weights, wherein the review sampling map includes a set of review locations on the one or more samples to review with the review tool, wherein the diversity weights control impacts of the one or more diversity factors on the review sampling map; and
direct the review tool to review the set of review locations on the one or more samples.

24. The inspection system of claim 23, wherein the inspection sub-system comprises:
an optical inspection sub-system.

25. The inspection system of claim 24, wherein the inspection sub-system comprises:
a darkfield optical inspection sub-system.

26. The inspection system of claim 23, wherein the review tool comprises:
a scanning electron microscope.

27. The inspection system of claim 23, wherein the sample scores are proportional to outputs of an automated sensitivity tuner that selects values of detection parameters of a detection model to achieve a desired detection rate of probable defects relative to total defect count, wherein the detection model identifies the defect events from the inspection data by comparing the inspection data to reference data and applying thresholds associated with the detection parameters.

28. The inspection system of claim 27, wherein the automated sensitivity tuner includes an unsupervised model to assign outlier rankings to the defect events from the hot scan, wherein the sample scores are proportional to the outlier rankings.

29. The inspection system of claim 27, wherein the automated sensitivity tuner includes a supervised model, wherein the sample scores are proportional to an output of the supervised model.

30. The inspection system of claim 23, wherein the one or more diversity factors comprise:
at least one of diversity of locations across a sample of the one or more samples, diversity of predefined regions associated with the one or more samples, class diversity associated with two or more defect classes.

31. The inspection system of claim 23, wherein at least one of the one or more diversity factors comprises:
a suppression factor that de-weights undesired defects.

32. An inspection method comprising:
receiving inspection data for one or more samples from an inspection tool;
assigning sample scores to defect events from a hot scan associated with the inspection data;
selecting values of diversity weights for one or more diversity factors;
generating a review sampling map based on the sample scores and the diversity weights, wherein the review sampling map includes a set of review locations on the one or more samples to review with a review tool, wherein the diversity weights control impacts of the one or more diversity factors on the review sampling map; and
directing the review tool to review the set of review locations on the one or more samples.
